(19) United States
(12) Patent Application Publication
(10) Pub. No.: US 2024/0332260 A1
(43) Pub. Date: Oct. 3, 2024

(54) PACKAGE ARCHITECTURES FOR DIFFERENTIATED ARTIFICIAL-REALITY TASK-SPECIFIC CHIPLETS

(71) Applicant: Meta Platforms Technologies, LLC, Menlo Park, CA (US)

(72) Inventors: Sunil Gupta, San Diego, CA (US); Rajendra D. Pendse, Fremont, CA (US)

(21) Appl. No.: 18/617,001

(22) Filed: Mar. 26, 2024

Related U.S. Application Data
(60) Provisional application No. 63/493,944, filed on Apr. 3, 2023.

(51) Int. Cl. H01L 25/065; G06V 10/94; H01L 23/00; H01L 23/48; H01L 23/538; H01L 25/10

(52) U.S. Cl. CPC H01L 25/0657; H01L 23/481; H01L 23/5383; H01L 24/08; H01L 24/16; H01L 25/105; G06V 10/94; H01L 2224/08145; H01L 2224/16225

(57) ABSTRACT

An artificial-reality system including (1) an output device, (2) one or more real-world sensors, and (3) an integrated-circuit package including (A) a general-purpose system-on-chip having a first die-to-die interface and (B) a differentiated artificial-reality task-specific chiplet having a second die-to-die interface coupled to the first die-to-die interface of the general-purpose system-on-chip. The differentiated artificial-reality task-specific chiplet may be configured to generate an output by performing one or more differentiated artificial-reality processing tasks on one or more inputs derived from the one or more real-world sensors, and the general-purpose system-on-chip may be configured to present, via the output device, an artificial reality to a user based at least in part on the output of the differentiated artificial-reality task-specific chiplet. Various other apparatuses, systems, and methods are also disclosed.

### CROSS REFERENCE TO RELATED APPLICATION

This application claims the benefit of U.S. Provisional Application No. 63/493,944, filed 3 Apr. 2023, and titled AR/VR CHIPLET ARCHITECTURE, the disclosure of which is incorporated, in its entirety, by this reference.

### BRIEF DESCRIPTION OF THE DRAWINGS

The accompanying drawings illustrate a number of exemplary embodiments and are a part of the specification. Together with the following description, these drawings demonstrate and explain various principles of the present disclosure.

FIG. 1 is an illustration of an example artificial-reality system having a differentiated artificial-reality task-specific chiplet according to embodiments of this disclosure.

FIG. 2 illustrates an example artificial-reality system having an example multi-chip package according to at least one embodiment of this disclosure.

FIG. 3 illustrates an example artificial-reality system having an example multi-chip package according to at least one embodiment of this disclosure.

FIG. 4 illustrates an example artificial-reality system having an example multi-chip package according to at least one embodiment of this disclosure.

FIG. 5 illustrates an example artificial-reality system having an example multi-chip package according to at least one embodiment of this disclosure.

FIG. 6 is an illustration of an example artificial-reality headset architecture according to embodiments of this disclosure.

FIG. 7 is an illustration of exemplary augmented-reality glasses that may be used in connection with embodiments of this disclosure.

FIG. 8 is an illustration of an exemplary virtual-reality headset that may be used in connection with embodiments of this disclosure.

FIG. 9 is an illustration of exemplary haptic devices that may be used in connection with embodiments of this disclosure.

FIG. 10 is an illustration of an exemplary virtual-reality environment according to embodiments of this disclosure.

FIG. 11 is an illustration of an exemplary augmented-reality environment according to embodiments of this disclosure.

FIG. 12 an illustration of an exemplary system that incorporates an eye-tracking subsystem capable of tracking a user's eye(s).

FIG. 13 is a more detailed illustration of various aspects of the eye-tracking subsystem illustrated in FIG. 12.

FIGS. 14A and 14B are illustrations of an exemplary human-machine interface configured to be worn around a user's lower arm or wrist.

FIGS. 15A and 15B are illustrations of an exemplary schematic diagram with internal components of a wearable system.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the present disclosure covers all modifications, equivalents, and alternatives falling within the scope of the appended claims.

### DETAILED DESCRIPTION OF EXEMPLARY EMBODIMENTS

Companies that specialize in advanced technology products often use off-the-shelf System-on-Chips (SoCs). The versatility of an SoC enables its use across multiple industries, serving a diverse array of customer companies. However, the generic nature of these SoCs may not meet specific demands or optimizations required for specialized applications, which can potentially hinder product differentiation in the market. Early adoption of unique features might require collaboration with chip manufacturers to customize these SoCs. This could introduce constraints in customization, compatibility challenges, or suboptimal performance, all of which may impact the user experience and technological capabilities. Furthermore, if competitors gain access to these customized features via standard SoCs, it could undermine a company's competitive edge. The pressure on SoC manufacturers to incorporate a variety of features for different sectors may not align with the precise requirements of SoC technology, potentially compromising performance and user experience. This could lengthen development periods, increase costs, and dilute focused innovation efforts critical for maintaining industry leadership.

The present disclosure generally describes system and package configurations that pair a differentiated artificial-reality task-specific chiplet with a general-purpose SoC through a die-to-die (or logic-logic) interface. The die-to-die interface may be a high-speed, low-latency, high-bandwidth, and low-power interface. The differentiated artificial-reality task-specific chiplet and the general-purpose SoC may be paired using a suitable 2D, 2.5D, and/or 3D packaging solution. These packaging solutions may employ a combination of fan-out wafer-level packaging (WLP) and laminate substrate technologies. A 3D version may provide a small form-factor along with superior bandwidth and power.

Integrating a differentiated artificial-reality task-specific chiplet with a general-purpose System on Chip (SoC) may offer substantial benefits for a company specializing in advanced technology products. This approach may enable the incorporation of specialized functionalities tailored to the company's unique requirements, enhancing performance and user experience in ways that generic SoCs may be unable to match. The disclosed customized chiplets may provide optimized processing capabilities or additional features that may be critical for the company's specific applications, allowing for differentiation in a competitive market. Furthermore, this method may maintain the flexibility and scalability provided by the general-purpose SoC, which may ensure a balanced approach to innovation and cost-effectiveness. This integration may also allow for rapid adaptation to evolving technological trends and market demands, as the modular nature of combining chiplets with SoCs may facilitate easier updates and upgrades. This strategy may also align with the need for targeted innovation and may support efficient resource utilization and potentially faster time-to-market for new or improved products.

The disclosed differentiated artificial-reality task-specific chiplets and/or associated package architectures may enhance product distinctiveness by providing a mechanism that allows companies to embed unique features and optimizations into their products, fostering market differentiation and potentially increasing market share. These chiplets and/or package architectures may offer increased customization flexibility, enabling companies to refine system-on-chips to align closely with their specific needs and the envisioned capabilities and user experiences of their products. By offering a strategy that deters competitors from easily replicating or enhancing a company's distinctive features, the disclosed differentiated artificial-reality task-specific chiplets and/or associated package architectures may contribute to sustaining a competitive edge, supporting a company's market leadership. Furthermore, by addressing the challenges described above, the disclosed chiplets and/or package architectures may streamline the development process, reduce associated costs, and minimize the diversion of focus from innovation, enabling companies to introduce superior products more quickly and efficiently, enhancing their competitive stance and financial results. These and other embodiments, features, and advantages will be more fully understood upon reading the following detailed description in conjunction with the accompanying drawings and claims.

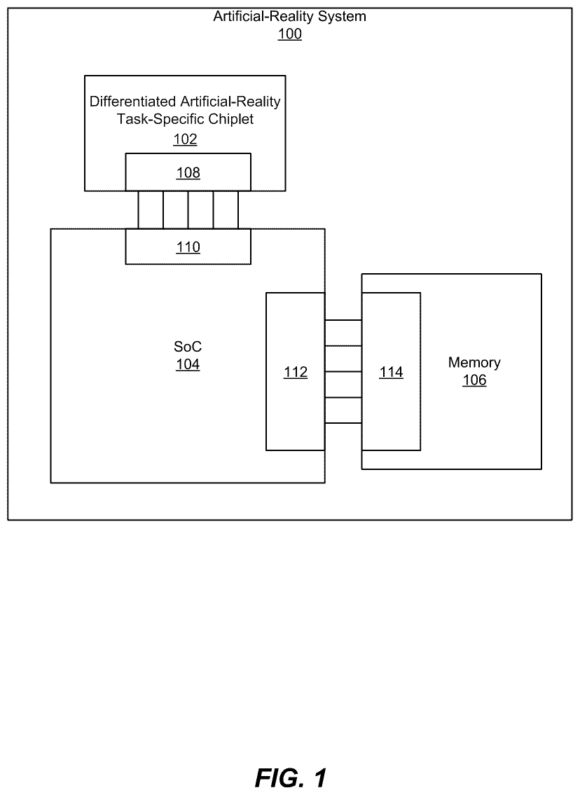

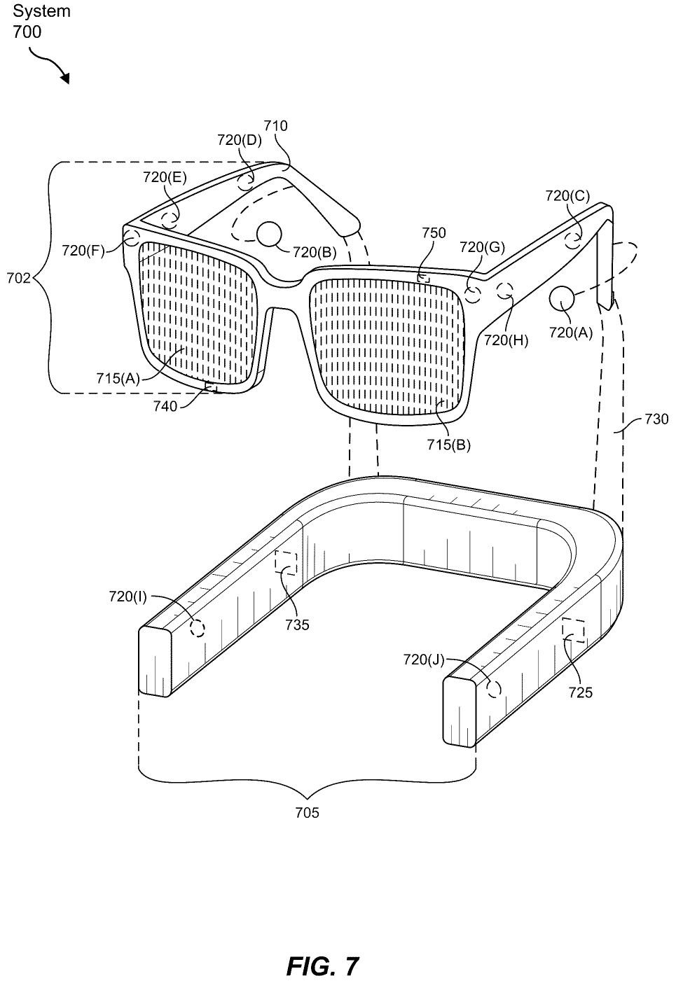

The following will provide, with reference to FIGS. 1-6, detailed descriptions of package architectures for differentiated artificial-reality task-specific chiplets. With reference to FIGS. 7-15, the following will provide detailed descriptions of various extended-reality systems and components that may implement embodiments of the present disclosure.

As used herein, the term “System-on-Chip” (SoC) may generally refer to an integrated circuit (IC) that integrates all or most components of a computer or other electronic system onto a single chip, which may include, but may not be limited to, a chiplet or a logic chiplet. As used herein, the term “general-purpose SoC” may generally refer to an integrated circuit (IC) that integrates all or most necessary electronic circuits and components of a computer or other electronic system onto a single chip. A general-purpose SoC may be designed to support a wide array of applications and may not be tailored to any specific task or market segment. A general-purpose SoC may include processing units, memory blocks, communication interfaces, and other necessary peripherals that enable it to perform a variety of functions without the need for additional external components.

As used herein, the term “chiplet” may generally refer to a die or a thin piece of silicon. For example, and without limitation, a chiplet may include a thin piece of silicon on which components, such as transistors, diodes, resistors, and other components, are housed to fabricate a functional electronic circuit. In some examples, a chiplet may generally refer to a small-scale integrated circuit (IC) having a defined subset of functionality. Multiple chiplets may be combined in a single package assembly or module, with the combination of chiplets being selected and arranged to perform desired functionalities for a particular device and/or system. In some examples, a “logic chiplet” may correspond to a chiplet that contains a majority of the logic components (e.g., transistors) of the electronic circuit of a semiconductor device. In some examples, a logic chiplet may include all or some of the functionality of a SoC. In at least one example, two or more logic chiplets may form a partitioned SoC where each logic chiplet may be dedicated to specific functions or tasks of the partitioned SoC. In this context, a “logic chiplet” may refer to a chiplet that primarily houses logic components (e.g., transistors) crucial for the SoC's computational operations. Such a logic chiplet might encapsulate all or a subset of the capabilities typically associated with a general-purpose SoC. Furthermore, a general-purpose SoC may be engineered to work in conjunction with one or more logic chiplets, with each chiplet designated specific functions or roles, thereby enhancing the SoC's versatility and efficiency in handling a variety of tasks and applications. This configuration may allow the general-purpose SoC to utilize the distinct functionalities provided by the chiplets, augmenting the system's flexibility and performance across different operational scenarios.

As used herein, the term “differentiated artificial-reality task-specific chiplet” may generally refer to a chiplet that captures or embodies differentiating and customized integrated-circuit intellectual property. In some examples, a differentiated artificial-reality task-specific chiplet may be designed with distinctive features, enabling it to integrate seamlessly into specific product architectures. A differentiated artificial-reality task-specific chiplet may be tailored to perform a distinct set of processing tasks, which may closely align with a product's individual configuration or use case. A differentiated artificial-reality task-specific chiplet may allow for customization that caters to a particular product, system architecture, set of sensors, and/or artificial-reality use cases, which a general-purpose SoC may be unable to offer. In some examples, a differentiated artificial-reality task-specific chiplet may allow for the precise tailoring of SoCs to meet specific operational requirements and user expectations.

Examples of processing tasks that may be performed by the disclosed differentiated artificial-reality task-specific chiplets may include, without limitation, deep-learning processing (e.g., the chiplet may be used to process complex algorithms used in machine learning and artificial intelligence, allowing systems to learn and improve from experience), computer-vision processing (e.g., the chiplet may perform tasks related to enabling machines to see, interpret, and/or understand visual data from the real world), image processing (e.g., the chiplet may process digital images, applying various computational algorithms to enhance image quality or extract valuable information), sensor-data processing (e.g., the chiplet may handle processing sensor data, interpreting information from integrated sensors such as cameras, microphones, eye trackers, hand trackers, body trackers, gyroscopes, accelerometers, or temperature sensors), augmented-reality processing (e.g., the chiplet may be used for processing augmented reality tasks, such as overlaying digital information onto a real-world view), virtual-reality processing (e.g., the chiplet may process information related to creating and maintaining a comprehensive virtual environment, ensuring a smooth and immersive user experience), real-time 3D-graphics rendering (e.g., the chiplet may handle processing tasks related to rendering 3D graphics in real-time, an aspect of creating realistic visual experiences in games or simulations), audio processing (e.g., the chiplet may be responsible for processing audio signals, providing noise reduction, echo cancellation, or 3D audio effects), video processing (e.g., the chiplet may handle tasks such as video encoding, decoding, transcoding, or streaming, necessary for high-quality video playback and communication), natural-language processing (e.g., the chiplet may process and interpret human language in a valuable way, enabling voice recognition, language translation, or sentiment analysis), and/or artificial-intelligence-assistant processing (e.g., the chiplet may process natural language inputs, generate human-like responses, and perform complex computations needed for machine learning algorithms).

A “memory chiplet” may correspond to a chiplet that contains a majority of the memory components (e.g., static random access memory (SRAM), dynamic random access memory (DRAM), etc.) of the electronic circuit of a semiconductor device. In some examples, a “memory chiplet” may represent or be configured as cache memory for a connected logical chiplet.

The disclosed differentiated artificial-reality task-specific chiplets and/or general-purpose SoCs may be electrically and/or communicatively coupled via a suitable die-to-die interface. As used herein, the term “die-to-die interface” may generally refer to any architecture or protocol that facilitates communication, power delivery, or signal transmission between distinct semiconductor dies within a multi-die package. In at least one example, a die-to-die interface may be configured according to the Universal Chiplet Interconnect Express (UCIe) standard.

In some examples, the disclosed differentiated artificial-reality task-specific chiplets and/or general-purpose SoCs may be electrically and/or communicatively coupled via a suitable bridging die. The term “bridging chiplet,” as used herein, may represent a type of chiplet in semiconductor devices, primarily focusing on facilitating interconnections between various components. In some examples, a bridging chiplet may represent a passive interposer (e.g., a passthrough passive interposer with or without vias such as through-silicon vias), which may lack active components but serve to physically and electrically connect different chiplets, assisting in signal routing and/or providing mechanical support. Additionally or alternatively, a bridging chiplet may represent or include an active interposer, integrated with active electronic components like transistors, and capable of performing functions such as signal processing or power distribution, in addition to providing physical and electrical connections. In some examples, a bridging chiplet may represent or include integrated passive devices (IPDs) embedded passively with or without via such as through-silicon vias. Examples of integrated passive devices may include resistors, inductors, capacitors, transformers, diplexers, and/or filters such as low-pass filters or band-pass filters.

The term “auxiliary chiplet,” as used herein, may refer to a specialized type of silicon chiplet in semiconductor devices. Examples of auxiliary chiplets may include an integrated-voltage-regulator (IVR) chiplet, which may contain components for voltage regulation to provide a stable power supply, a deep-trench-capacitor (DTC) chiplet, featuring high-density capacitors for efficient energy storage and power management, an input/output (IO) chiplet, which may manage communication with external devices, a direct-to-direct (D2D) interface chiplet, which may enable direct communication and data transfer between chiplets, an analog-to-digital converter (ADC) and/or a digital-to-analog converter (DAC) chiplet, which may convert analog signals to digital data and/or vice versa, a radio-frequency (RF) chiplet, an artificial-intelligence (AI) chiplet, which may accelerate machine-learning and AI computations, an image-signal-processor (ISP) chiplet, which may process and enhance image data from sensors, and/or various co-processor or accelerator chiplets that may enhance specific computational tasks, variations or combinations of one or more of the same, and/or any other suitable auxiliary chiplet that may improve overall system performance and efficiency.

The terms “circuit” and/or “circuitry” as used herein, may generally refer to a complete circular path through which electricity flows. For example, and without limitation, a simple circuit may include a current source, conductors, and a load. The term circuit can be used in a general sense to refer to any fixed path through which electricity, data, or a signal can travel. The term “active circuitry” may represent or include sections of an electronic circuit that contain active electronic components like transistors, diodes, or integrated circuits. Active circuitry may be capable of amplifying power, controlling current flow, or performing other dynamic functions within the circuit. In some examples, “passive circuitry” may include parts of an electronic circuit that consist of passive components such as resistors, capacitors, and inductors, which may be used to attenuate signals, store energy, or provide resistance.

The term “memory,” as used herein, may generally refer to an electronic holding place for instructions and/or data used by a computer processor to perform computing functions. For example, and without limitation, a memory may correspond to metal-oxide-semiconductor (MOS) memory, volatile memory, non-volatile memory, and/or semi-volatile memory. Example types of memory may include static random access memory (SRAM) and/or dynamic access random memory (DRAM).

A “backside,” as used herein, may generally refer to a surface portion of a semiconductor chip, such as a chiplet, that is defined by a substrate. A plurality of electronic components and/or electrically conductive layers may be formed on a surface portion of the substrate opposite the backside. In some examples, “backside” may represent or include the surface of the semiconductor chip opposite to the frontside, devoid or substantially devoid of active electronic components. According to some examples, “backside” may represent or include the part of a flip chip that faces upwards, allowing for improved heat dissipation in the configuration.

A “frontside,” as used herein, may generally refer to a portion of a semiconductor chip, such as a chiplet, that is disposed opposite the backside. The frontside may face in a direction opposite a backside of the semiconductor chip and may be defined by and/or formed adjacent electronic components and/or electrically conductive layers disposed on a substrate of the semiconductor chip. In some examples, “frontside” may represent or include the surface of the semiconductor chip where integrated circuits and other functional elements are located. For example, active circuitry, such as active electrical connection regions (e.g., electrically conductive pads such as input/output (I/O) pads), may be exposed at the frontside of the semiconductor chip. Such active electrical connection regions may be positioned and configured to be electrically coupled to one or more components external to the semiconductor chip via suitable electrical interconnects (e.g., solder and/or other electrically conductive bumps, micro-bumps, etc.). According to some examples, “frontside” may represent or include the part of a flip chip that is flipped to face downwards towards the substrate for direct electrical connections.

FIG. 1 illustrates an example artificial-reality system 100 having a differentiated artificial-reality task-specific chiplet 102, a general-purpose SoC 104, and a memory 106. In this example, task-specific chiplet 102 and general-purpose SoC 104 may respectively include a die-to-die interface 108 and a die-to-die interface 110 that facilitates communication and data transfer between task-specific chiplet 102 and general-purpose SoC 104. In some examples, die-to-die interface 108 and die-to-die interface 110 may be operable according to a set of standards and protocols aimed at defining interconnects between chiplets within a package, facilitating communication and interoperability amongst diverse chiplets. Additionally or alternatively, die-to-die interface 108 and die-to-die interface 110 may be configured to exchange data based on any suitable on-package interconnect protocol designed to connect multiple chiplets or dies within a single integrated circuit package. In at least one example, die-to-die interface 108 and die-to-die interface 110 may each represent or include a universal chiplet interface, such as a universal chiplet interconnect express.

In some examples, SoC 104 may represent a monolithic general SoC that performs various functions as a single chip without (or with little) specialization. In some examples, SoC 104 may represent a general SoC designed for multiple customers and/or may include features that satisfy varying and/or different needs of the multiple customers. In artificial-reality system 100, certain functions may be performed by task-specific chiplet 102 rather than general-purpose SoC 104. For example, task-specific chiplet 102 may perform machine learning (e.g., as a deep-learning accelerator), computer vision, etc.

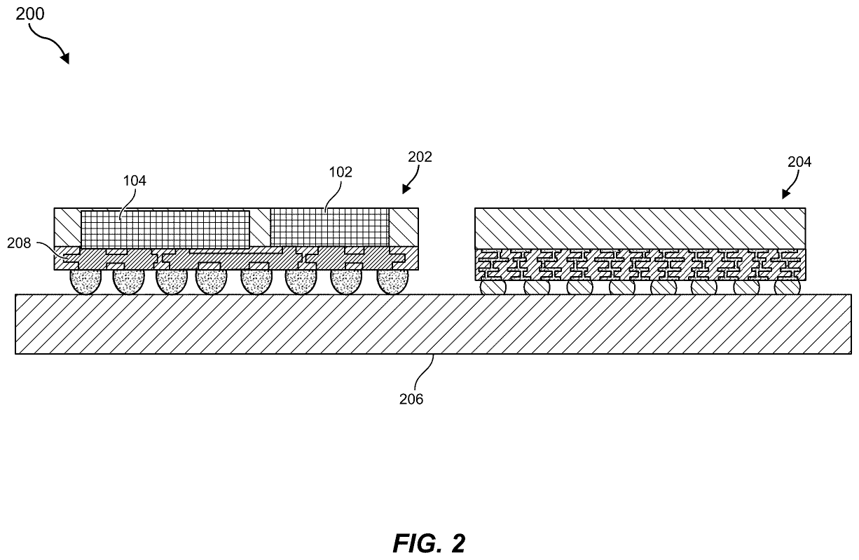

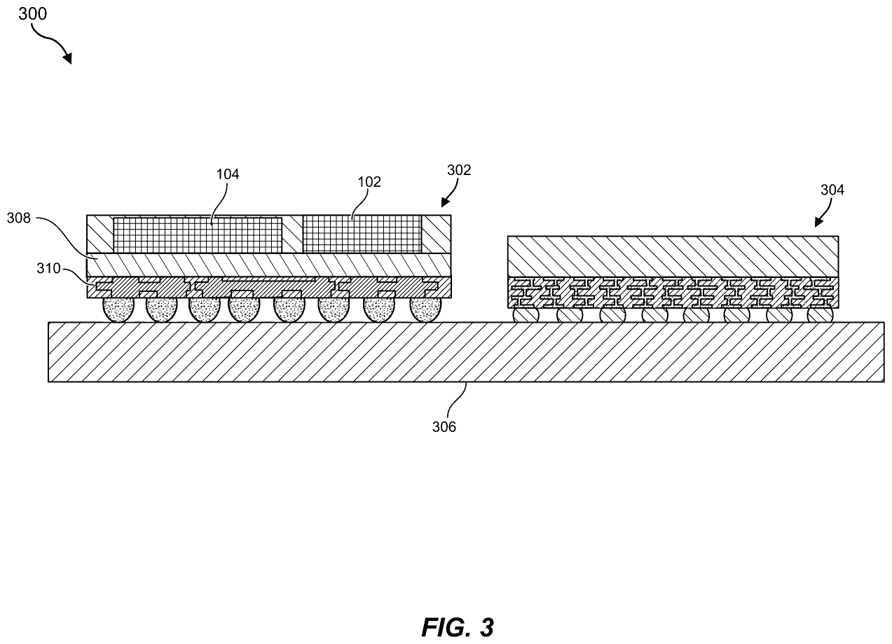

FIGS. 2 and 3 illustrate example package solutions of system 100. For example, FIG. 2 illustrates an example 2D configuration 200 that may include a logic package 202 coupled to a memory package 204 via a substrate 206. In this example, logic package 202 may include task-specific chiplet 102 and SoC 104 coupled together via interconnects 208 (e.g., redistribution layers of logic package 202), and memory package 204 may include memory 106. FIG. 3 illustrates an example 2.5D configuration 300 of system 100. In this example, logic package 302 may include task-specific chiplet 102 and SoC 104 coupled together via an interposer 308 (e.g., a silicon structure having interconnects at a finer pitch than may be available on a PCB, using semiconductor fabrication techniques), and memory package 304 may include memory 106.

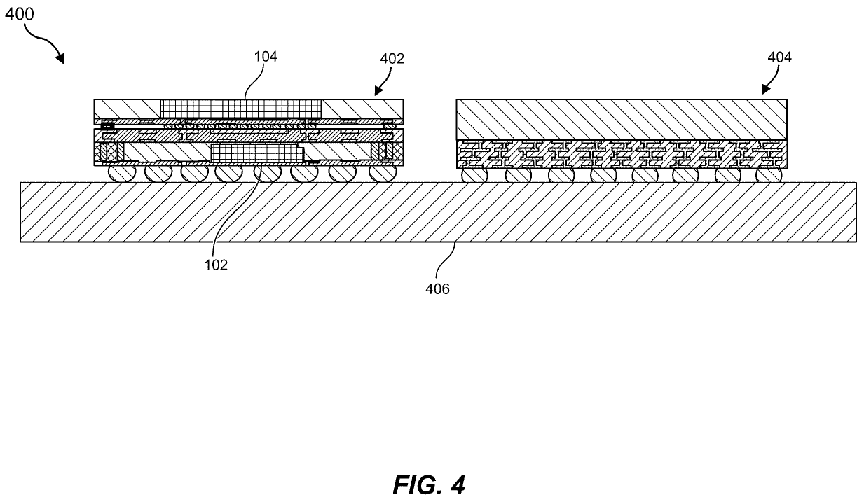

FIG. 4 illustrates an example 3D package configuration 400 of system 100 in FIG. 1 that may include a logic package 402 and a memory package 404 interconnected by a substrate 406 (e.g., a printed circuit board). As shown in FIG. 4, SoC 104 may be stacked on top of task-specific chiplet 102 (e.g., in a face-to-face, face-to-back, or a back-to-back orientation), which may provide superior bandwidth, latency, power performance and a smaller form-factor. Although not shown in FIG. 4, in some examples a bridge die may couple SoC 104 with task-specific chiplet 102. Additionally, in some examples, SoC 104 may require cooling (e.g., via active or passive cooling, not shown in FIG. 4) and therefore may have its backside exposed as illustrated in FIG. 4.

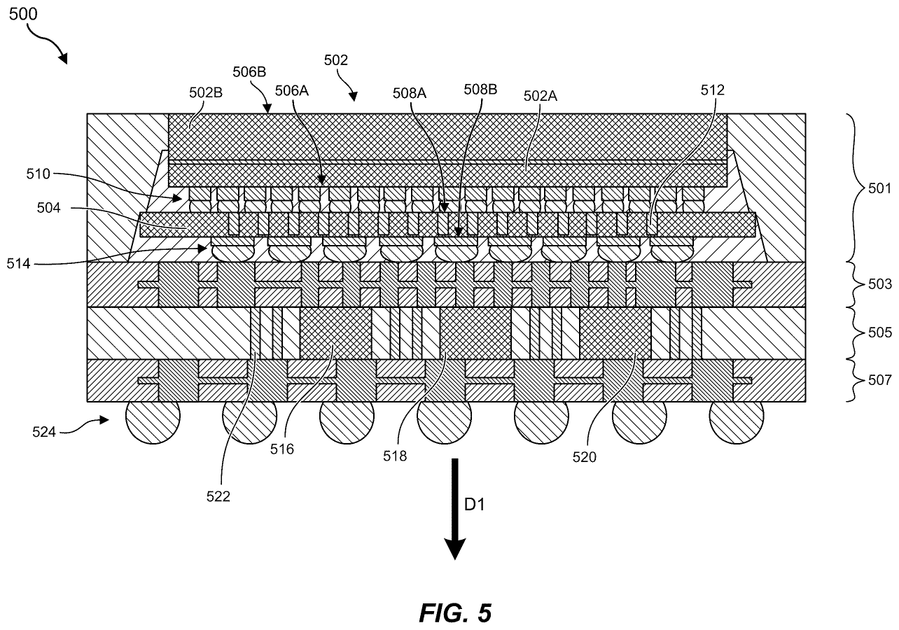

FIG. 5 illustrates an example multi-chip assembly 500 using face-to-face (F2F) in-package integration. In some examples, multi-chip package 500 may include a sub-package layer 501 and/or a sub-package layer 505. As shown, sub-package layer 501 may include a logic chiplet 502 (which may include a first logic die 502A hybrid bonded to a second logic die 502B) and a differentiated artificial-reality task-specific chiplet 504. In some examples, logic chiplet 502 may represent all or a portion of SoC 104 in FIG. 1, and differentiated artificial-reality task-specific chiplet 504 may represent all or a portion of task-specific chiplet 102 in FIG. 1.

As shown in FIG. 5, logic chiplet 502 and differentiated artificial-reality task-specific chiplet 504 may each have a frontside (face side, front surface, or active frontside surface) and a backside (back surface, backside surface, or substrate surface). For example, logic chiplet 502 may have a frontside 506A and a backside 506B disposed opposite frontside 506A, with frontside 506A and backside 506B facing in opposite directions. Similarly, differentiated artificial-reality task-specific chiplet 504 may have a frontside 508A and a backside 508B disposed on opposite sides and facing in opposite directions. In the example shown in FIG. 5, logic chiplet 502 is positioned with frontside 506A oriented facing in direction D1, and differentiated artificial-reality task-specific chiplet 504 is positioned with frontside 508A oriented facing frontside 506A of logic chiplet 502 and opposite direction D1. In this configuration, active circuitry of frontside 506A of logic chiplet 502 may be coupled to active circuitry of frontside 508A of differentiated artificial-reality task-specific chiplet 504 via one or more interconnects 510 (e.g., microbumps).

In some examples, multi-chip package 500 may include additional sub-package layers (e.g., sub-package layer 505) having one or more additional chiplets (e.g., auxiliary chiplets 516, 518, and 520). In at least one example, multi-chip package 500 may include one or more distribution layers, interposers, and/or redistribution layers (RDLs) (e.g., a distribution layer 503 and a distribution layer 507) to facilitate routing and interconnection between the components and sub-packages in multi-chip package 500. Active circuitry of frontside 506A of logic chiplet 502 may be coupled to distribution layer 503 through vias, such as through-silicon vias 512 of differentiated artificial-reality task-specific chiplet 504 or through-package vias of sub-package layer 501 (not shown). RDLs on two sides of a sub-package layer may be connected by through-package vias (such as through-package vias 522). RDLs of two separate sub-package layers may be connected by suitable interconnects, such as solder balls, solder bumps, and/or microbumps. In some examples, active circuitry of frontside 506A of logic chiplet 502 may be coupled to active circuitry of auxiliary chiplets 516, 518, and/or 520 via interconnects 514 and distribution layer 503. In the examples describe herein, sub-package layers and/or chiplets may be coupled to one another via RDL layers and/or any suitable chiplet-to-chiplet bonding technique.

As shown in FIG. 5, an array of interconnects 524 may be disposed on a bottom surface of multi-chip package 500. Interconnects 524 may enable mounting and electrical connection between components of multi-chip package 500, such as logic chiplet 502, and an external circuit board and/or one or more other electrical components of a device external to multi-chip package 500.

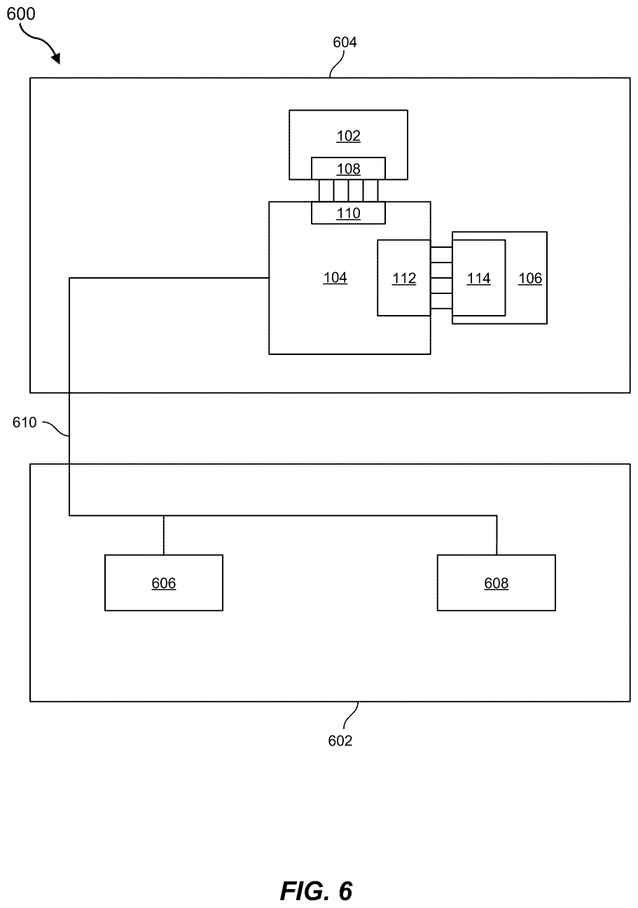

FIG. 6 illustrates a simplified diagram of an artificial-reality headset 600 having a frontside 602 and a backside 604. As shown, frontside 602 may include one or more output devices (e.g., an output device 606) and/or one or more real-world sensors (e.g., real-world sensor 608), and backside 604 may include task-specific chiplet 102, general-purpose SoC 104, and/or memory 106. In the example shown, output device 606 and/or real-world sensor 608 may communicate with SoC 104 and/or task-specific chiplet 102 through an interface 610 (e.g., a bus or a port).

In some examples, output device 606 may represent or include any piece of hardware in a computing system, such as a virtual reality (VR), augmented reality (AR), and AI-assistant computing system, that interprets data from the system and presents it to the user in a perceivable form. This form can include, but is not limited to, visual, audio, or tactile output. Examples of output device 606 may include, without limitation, monitors, projectors, heads-up displays, speakers, headphones, bone-conduction devices, tactile-output devices, vibrating controllers, wearable-haptic suits, and tactile-feedback gloves.

In some examples, real-world sensor 608 may represent or include a device or component that measures a physical property or change in a real-world environment and converts it into data that can be processed by a computing system, such as VR, AR, and AI-assistant systems. Examples of real-world sensor 608 may include, without limitation, motion sensors (e.g., accelerometers, gyroscopes, and infrared sensors that can track user movements and gestures), environmental sensors (e.g., ambient light sensors, temperature sensors, and humidity sensors that can provide data on the surrounding environment), proximity sensors that can detect the presence of nearby objects or users, biometric sensors (e.g., heart rate sensors, skin conductance sensors, and eye-tracking sensors) that can monitor physiological responses, audio sensors (e.g., microphones) that can capture sound and voice commands, and/or visual sensors (e.g., cameras and depth sensors) that can capture images and spatial information.

### EXAMPLE EMBODIMENTS

Example 1: An artificial-reality system including (1) an output device, (2) one or more real-world sensors, and (3) an integrated-circuit package including (A) a general-purpose system-on-chip having a first die-to-die interface and (B) a differentiated artificial-reality task-specific chiplet having a second die-to-die interface coupled to the first die-to-die interface of the general-purpose system-on-chip. In this example, the differentiated artificial-reality task-specific chiplet may be configured to generate an output by performing one or more differentiated artificial-reality processing tasks on one or more inputs derived from the one or more real-world sensors, and the general-purpose system-on-chip may be configured to present, via the output device, an artificial reality to a user based at least in part on the output of the differentiated artificial-reality task-specific chiplet.

Example 2: The artificial-reality system of Example 1 where the one or more differentiated artificial-reality processing tasks include a deep-learning operation.

Example 3: The artificial-reality system of any of Examples 1-2 where the one or more differentiated artificial-reality processing tasks include a computer-vision operation.

Example 4: The artificial-reality system of any of Examples 1-3 where the general-purpose system-on-chip includes an active frontside having first active circuitry, the differentiated artificial-reality task-specific chiplet includes an active frontside having second active circuitry, the active frontside of the general-purpose system-on-chip faces a first direction, and the active frontside of the differentiated artificial-reality task-specific chiplet faces a second direction opposite the first direction.

Example 5: The artificial-reality system of any of Examples 1-4 further including a redistribution layer. In this example, the differentiated artificial-reality task-specific chiplet may further include vias through which the general-purpose system-on-chip may be electrically coupled to the redistribution layer.

Example 6: The artificial-reality system of any of Examples 1-5 further including (1) a front housing configured to be worn against the face of the user, the front housing including the output device and the real-world sensor, and (2) a rear housing configured to be worn against the back of the user's head, the rear housing including the general-purpose system-on-chip and the differentiated artificial-reality task-specific chiplet.

Example 7: The artificial-reality system of any of Examples 1-6 where the integrated-circuit package further includes an interposer, and the general-purpose system-on-chip and the differentiated artificial-reality task-specific chiplet are coupled together via the interposer.

Example 8: The artificial-reality system of any of Examples 1-7 where the integrated-circuit package further includes a redistribution layer, and the general-purpose system-on-chip and the differentiated artificial-reality task-specific chiplet are coupled together via the redistribution layer.

Example 9: The artificial-reality system of any of Examples 1-8 where the first die-to-die interface of the general-purpose system-on-chip and the second die-to-die interface of the differentiated artificial-reality task-specific chiplet are universal chiplet interconnects.

Example 10: A multi-chiplet assembly including (1) a general-purpose system-on-chip including (A) an active frontside having first active circuitry and (B) a first die-to-die interface coupled to the first active circuitry and (2) a differentiated artificial-reality task-specific chiplet including (C) an active frontside having second active circuitry and (D) a second die-to-die interface coupled to the second active circuitry and the first die-to-die interface of the general-purpose system-on-chip. In this example, the differentiated artificial-reality task-specific chiplet may be configured to generate an output by performing one or more differentiated artificial-reality processing tasks on one or more inputs derived from the one or more real-world sensors, and the general-purpose system-on-chip may be configured to present, via an output device, an artificial reality to a user based at least in part on the output of the differentiated artificial-reality task-specific chiplet.

Example 11: The multi-chiplet assembly of Examples 10 where the one or more differentiated artificial-reality processing tasks include a deep-learning operation.

Example 12: The multi-chiplet assembly of any of Examples 10-11 where the one or more differentiated artificial-reality processing tasks include a computer-vision operation.

Example 13: The multi-chiplet assembly of any of Examples 10-12 where the active frontside of the general-purpose system-on-chip faces a first direction, and the active frontside of the differentiated artificial-reality task-specific chiplet faces a second direction opposite the first direction.

Example 14: The multi-chiplet assembly of any of Examples 10-13 further including a redistribution layer. In this example, the differentiated artificial-reality task-specific chiplet may further include vias through which the first active circuitry of the general-purpose system-on-chip may be electrically coupled to the redistribution layer.

Example 15: The multi-chiplet assembly of any of Examples 10-14 further including an interposer. In this example, the general-purpose system-on-chip and the differentiated artificial-reality task-specific chiplet may be coupled together via the interposer.

Example 16: The multi-chiplet assembly of any of Examples 10-15 further including a redistribution layer. In this example, the general-purpose system-on-chip and the differentiated artificial-reality task-specific chiplet may be coupled together via the redistribution layer.

Example 17: The multi-chiplet assembly of any of Examples 10-16 where the first die-to-die interface of the general-purpose system-on-chip and the second die-to-die interface of the differentiated artificial-reality task-specific chiplet are universal chiplet interconnects.

Example 18: A multi-chiplet assembly including (1) a general-purpose system-on-chip including (A) an active frontside having first active circuitry and (B) a first die-to-die interface coupled to the first active circuitry and (2) a differentiated artificial-reality task-specific chiplet including (C) an active frontside having second active circuitry and (D) a second die-to-die interface coupled to the second active circuitry and the first die-to-die interface of the general-purpose system-on-chip. In this example, the active frontside of the general-purpose system-on-chip may face a first direction, and the active frontside of the differentiated artificial-reality task-specific chiplet may face a second direction opposite the first direction.

Example 19: The multi-chiplet assembly of Example 18 further including a redistribution layer. In this example, the differentiated artificial-reality task-specific chiplet may further include vias through which the first active circuitry of the general-purpose system-on-chip may be electrically coupled to the redistribution layer.

Example 20: The multi-chiplet assembly of any of Examples 18-19 where the first die-to-die interface of the general-purpose system-on-chip and the second die-to-die interface of the differentiated artificial-reality task-specific chiplet are universal chiplet interconnects.

Embodiments of the present disclosure may include or be implemented in conjunction with various types of artificial-reality systems. Artificial reality is a form of reality that has been adjusted in some manner before presentation to a user, which may include, for example, a virtual reality, an augmented reality, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a three-dimensional (3D) effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

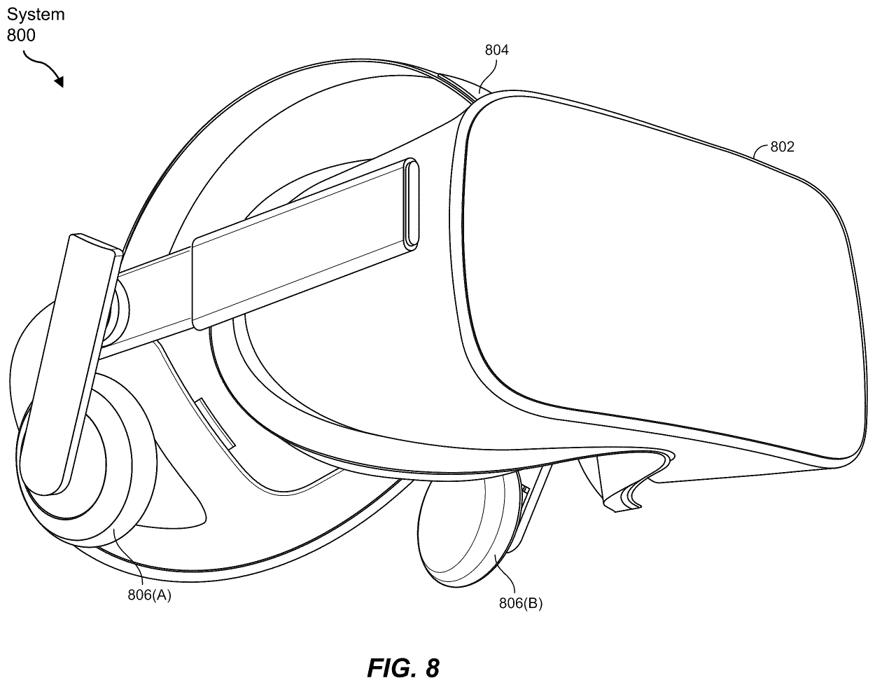

Artificial-reality systems may be implemented in a variety of different form factors and configurations. Some artificial-reality-systems may be designed to work without near-eye displays (NEDs). Other artificial-reality systems may include an NED that also provides visibility into the real world (such as, e.g., augmented-reality system 700 in FIG. 7) or that visually immerses a user in an artificial reality (such as, e.g., virtual-reality system 800 in FIG. 8). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

Turning to FIG. 7, augmented-reality system 700 may include an eyewear device 702 with a frame 710 configured to hold a left display device 715 (A) and a right display device 715 (B) in front of a user's eyes. Display devices 715 (A) and 715 (B) may act together or independently to present an image or series of images to a user. While augmented-reality system 700 includes two displays, embodiments of this disclosure may be implemented in augmented-reality systems with a single NED or more than two NEDs.

In some embodiments, augmented-reality system 700 may include one or more sensors, such as sensor 740. Sensor 740 may generate measurement signals in response to motion of augmented-reality system 700 and may be located on substantially any portion of frame 710. Sensor 740 may represent one or more of a variety of different sensing mechanisms, such as a position sensor, an inertial measurement unit (IMU), a depth camera assembly, a structured light emitter and/or detector, or any combination thereof. In some embodiments, augmented-reality system 700 may or may not include sensor 740 or may include more than one sensor. In embodiments in which sensor 740 includes an IMU, the IMU may generate calibration data based on measurement signals from sensor 740. Examples of sensor 740 may include, without limitation, accelerometers, gyroscopes, magnetometers, other suitable types of sensors that detect motion, sensors used for error correction of the IMU, or some combination thereof.

In some examples, augmented-reality system 700 may also include a microphone array with a plurality of acoustic transducers 720(A)-720(J), referred to collectively as acoustic transducers 720. Acoustic transducers 720 may represent transducers that detect air pressure variations induced by sound waves. Each acoustic transducer 720 may be configured to detect sound and convert the detected sound into an electronic format (e.g., an analog or digital format). The microphone array in FIG. 7 may include, for example, ten acoustic transducers: 720(A) and 720(B), which may be designed to be placed inside a corresponding ear of the user, acoustic transducers 720(C), 720(D), 720(E), 720(F), 720(G), and 720(H), which may be positioned at various locations on frame 710, and/or acoustic transducers 720(I) and 720(J), which may be positioned on a corresponding neckband 705.

In some embodiments, one or more of acoustic transducers 720(A)-(J) may be used as output transducers (e.g., speakers). For example, acoustic transducers 720(A) and/or 720(B) may be earbuds or any other suitable type of headphone or speaker.

The configuration of acoustic transducers 720 of the microphone array may vary. While augmented-reality system 700 is shown in FIG. 7 as having ten acoustic transducers 720, the number of acoustic transducers 720 may be greater or less than ten. In some embodiments, using higher numbers of acoustic transducers 720 may increase the amount of audio information collected and/or the sensitivity and accuracy of the audio information. In contrast, using a lower number of acoustic transducers 720 may decrease the computing power required by an associated controller 750 to process the collected audio information. In addition, the position of each acoustic transducer 720 of the microphone array may vary. For example, the position of an acoustic transducer 720 may include a defined position on the user, a defined coordinate on frame 710, an orientation associated with each acoustic transducer 720, or some combination thereof.

Acoustic transducers 720(A) and 720(B) may be positioned on different parts of the user's ear, such as behind the pinna, behind the tragus, and/or within the auricle or fossa. Or, there may be additional acoustic transducers 720 on or surrounding the ear in addition to acoustic transducers 720 inside the ear canal. Having an acoustic transducer 720 positioned next to an ear canal of a user may enable the microphone array to collect information on how sounds arrive at the ear canal. By positioning at least two of acoustic transducers 720 on either side of a user's head (e.g., as binaural microphones), augmented-reality device 700 may simulate binaural hearing and capture a 3D stereo sound field around about a user's head. In some embodiments, acoustic transducers 720(A) and 720(B) may be connected to augmented-reality system 700 via a wired connection 730, and in other embodiments acoustic transducers 720(A) and 720(B) may be connected to augmented-reality system 700 via a wireless connection (e.g., a BLUETOOTH connection). In still other embodiments, acoustic transducers 720(A) and 720(B) may not be used at all in conjunction with augmented-reality system 700.

Acoustic transducers 720 on frame 710 may be positioned in a variety of different ways, including along the length of the temples, across the bridge, above or below display devices 715 (A) and 715 (B), or some combination thereof. Acoustic transducers 720 may also be oriented such that the microphone array is able to detect sounds in a wide range of directions surrounding the user wearing the augmented-reality system 700. In some embodiments, an optimization process may be performed during manufacturing of augmented-reality system 700 to determine relative positioning of each acoustic transducer 720 in the microphone array.

In some examples, augmented-reality system 700 may include or be connected to an external device (e.g., a paired device), such as neckband 705. Neckband 705 generally represents any type or form of paired device. Thus, the following discussion of neckband 705 may also apply to various other paired devices, such as charging cases, smart watches, smart phones, wrist bands, other wearable devices, hand-held controllers, tablet computers, laptop computers, other external compute devices, etc.

As shown, neckband 705 may be coupled to eyewear device 702 via one or more connectors. The connectors may be wired or wireless and may include electrical and/or non-electrical (e.g., structural) components. In some cases, eyewear device 702 and neckband 705 may operate independently without any wired or wireless connection between them. While FIG. 7 illustrates the components of eyewear device 702 and neckband 705 in example locations on eyewear device 702 and neckband 705, the components may be located elsewhere and/or distributed differently on eyewear device 702 and/or neckband 705. In some embodiments, the components of eyewear device 702 and neckband 705 may be located on one or more additional peripheral devices paired with eyewear device 702, neckband 705, or some combination thereof.

Pairing external devices, such as neckband 705, with augmented reality eyewear devices may enable the eyewear devices to achieve the form factor of a pair of glasses while still providing sufficient battery and computation power for expanded capabilities. Some or all of the battery power, computational resources, and/or additional features of augmented-reality system 700 may be provided by a paired device or shared between a paired device and an eyewear device, thus reducing the weight, heat profile, and form factor of the eyewear device overall while still retaining desired functionality. For example, neckband 705 may allow components that would otherwise be included on an eyewear device to be included in neckband 705 since users may tolerate a heavier weight load on their shoulders than they would tolerate on their heads. Neckband 705 may also have a larger surface area over which to diffuse and disperse heat to the ambient environment. Thus, neckband 705 may allow for greater battery and computation capacity than might otherwise have been possible on a stand-alone eyewear device. Since weight carried in neckband 705 may be less invasive to a user than weight carried in eyewear device 702, a user may tolerate wearing a lighter eyewear device and carrying or wearing the paired device for greater lengths of time than a user would tolerate wearing a heavy standalone eyewear device, thereby enabling users to more fully incorporate artificial-reality environments into their day-to-day activities.

Neckband 705 may be communicatively coupled with eyewear device 702 and/or to other devices. These other devices may provide certain functions (e.g., tracking, localizing, depth mapping, processing, storage, etc.) to augmented-reality system 700. In the embodiment of FIG. 7, neckband 705 may include two acoustic transducers (e.g., 720 (l) and 720(J)) that are part of the microphone array (or potentially form their own microphone subarray). Neckband 705 may also include a controller 725 and a power source 735.

Acoustic transducers 720 (l) and 720(J) of neckband 705 may be configured to detect sound and convert the detected sound into an electronic format (analog or digital). In the embodiment of FIG. 7, acoustic transducers 720(I) and 720(J) may be positioned on neckband 705, thereby increasing the distance between the neckband acoustic transducers 720(I) and 720(J) and other acoustic transducers 720 positioned on eyewear device 702. In some cases, increasing the distance between acoustic transducers 720 of the microphone array may improve the accuracy of beamforming performed via the microphone array. For example, if a sound is detected by acoustic transducers 720(C) and 720(D) and the distance between acoustic transducers 720(C) and 720(D) is greater than, e.g., the distance between acoustic transducers 720(D) and 720(E), the determined source location of the detected sound may be more accurate than if the sound had been detected by acoustic transducers 720(D) and 720(E).

Controller 725 of neckband 705 may process information generated by the sensors on neckband 705 and/or augmented-reality system 700. For example, controller 725 may process information from the microphone array that describes sounds detected by the microphone array. For each detected sound, controller 725 may perform a direction-of-arrival (DOA) estimation to estimate a direction from which the detected sound arrived at the microphone array. As the microphone array detects sounds, controller 725 may populate an audio data set with the information. In embodiments in which augmented-reality system 700 includes an inertial measurement unit, controller 725 may compute all inertial and spatial calculations from the IMU located on eyewear device 702. A connector may convey information between augmented-reality system 700 and neckband 705 and between augmented-reality system 700 and controller 725. The information may be in the form of optical data, electrical data, wireless data, or any other transmittable data form. Moving the processing of information generated by augmented-reality system 700 to neckband 705 may reduce weight and heat in eyewear device 702, making it more comfortable to the user.

Power source 735 in neckband 705 may provide power to eyewear device 702 and/or to neckband 705. Power source 735 may include, without limitation, lithium-ion batteries, lithium-polymer batteries, primary lithium batteries, alkaline batteries, or any other form of power storage. In some cases, power source 735 may be a wired power source. Including power source 735 on neckband 705 instead of on eyewear device 702 may help better distribute the weight and heat generated by power source 735.

As noted, some artificial-reality systems may, instead of blending an artificial reality with actual reality, substantially replace one or more of a user's sensory perceptions of the real world with a virtual experience. One example of this type of system is a head-worn display system, such as virtual-reality system 800 in FIG. 8, that mostly or completely covers a user's field of view. Virtual-reality system 800 may include a front rigid body 802 and a band 804 shaped to fit around a user's head. Virtual-reality system 800 may also include output audio transducers 806(A) and 806(B). Furthermore, while not shown in FIG. 8, front rigid body 802 may include one or more electronic elements, including one or more electronic displays, one or more inertial measurement units (IMUs), one or more tracking emitters or detectors, and/or any other suitable device or system for creating an artificial-reality experience.

Artificial-reality systems may include a variety of types of visual feedback mechanisms. For example, display devices in augmented-reality system 700 and/or virtual-reality system 800 may include one or more liquid crystal displays (LCDs), light emitting diode (LED) displays, microLED displays, organic LED (OLED) displays, digital light project (DLP) micro-displays, liquid crystal on silicon (LCoS) micro-displays, and/or any other suitable type of display screen. These artificial-reality systems may include a single display screen for both eyes or may provide a display screen for each eye, which may allow for additional flexibility for varifocal adjustments or for correcting a user's refractive error. Some of these artificial-reality systems may also include optical subsystems having one or more lenses (e.g., concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some of the artificial-reality systems described herein may include one or more projection systems. For example, display devices in augmented-reality system 700 and/or virtual-reality system 800 may include micro-LED projectors that project light (using, e.g., a waveguide) into display devices, such as clear combiner lenses that allow ambient light to pass through. The display devices may refract the projected light toward a user's pupil and may enable a user to simultaneously view both artificial-reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial-reality systems may also be configured with any other suitable type or form of image projection system, such as retinal projectors used in virtual retina displays.

The artificial-reality systems described herein may also include various types of computer vision components and subsystems. For example, augmented-reality system 700 and/or virtual-reality system 800 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial-reality system may process data from one or more of these sensors to identify a location of a user, to map the real world, to provide a user with context about real-world surroundings, and/or to perform a variety of other functions.

The artificial-reality systems described herein may also include one or more input and/or output audio transducers. Output audio transducers may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

In some embodiments, the artificial-reality systems described herein may also include tactile (i.e., haptic) feedback systems, which may be incorporated into headwear, gloves, body suits, handheld controllers, environmental devices (e.g., chairs, floormats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial-reality devices, within other artificial-reality devices, and/or in conjunction with other artificial-reality devices.

By providing haptic sensations, audible content, and/or visual content, artificial-reality systems may create an entire virtual experience or enhance a user's real-world experience in a variety of contexts and environments. For instance, artificial-reality systems may assist or extend a user's perception, memory, or cognition within a particular environment. Some systems may enhance a user's interactions with other people in the real world or may enable more immersive interactions with other people in a virtual world. Artificial-reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial-reality experience in one or more of these contexts and environments and/or in other contexts and environments.

Some augmented-reality systems may map a user's and/or device's environment using techniques referred to as “simultaneous location and mapping” (SLAM). SLAM mapping and location identifying techniques may involve a variety of hardware and software tools that can create or update a map of an environment while simultaneously keeping track of a user's location within the mapped environment. SLAM may use many different types of sensors to create a map and determine a user's position within the map.

SLAM techniques may, for example, implement optical sensors to determine a user's location. Radios including WiFi, BLUETOOTH, global positioning system (GPS), cellular or other communication devices may be also used to determine a user's location relative to a radio transceiver or group of transceivers (e.g., a WiFi router or group of GPS satellites). Acoustic sensors such as microphone arrays or 2D or 3D sonar sensors may also be used to determine a user's location within an environment. Augmented-reality and virtual-reality devices (such as systems 700 and 800 of FIGS. 7 and 8, respectively) may incorporate any or all of these types of sensors to perform SLAM operations such as creating and continually updating maps of the user's current environment. In at least some of the embodiments described herein, SLAM data generated by these sensors may be referred to as “environmental data” and may indicate a user's current environment. This data may be stored in a local or remote data store (e.g., a cloud data store) and may be provided to a user's AR/VR device on demand.

When the user is wearing an augmented-reality headset or virtual-reality headset in a given environment, the user may be interacting with other users or other electronic devices that serve as audio sources. In some cases, it may be desirable to determine where the audio sources are located relative to the user and then present the audio sources to the user as if they were coming from the location of the audio source. The process of determining where the audio sources are located relative to the user may be referred to as “localization,” and the process of rendering playback of the audio source signal to appear as if it is coming from a specific direction may be referred to as “spatialization.”

Localizing an audio source may be performed in a variety of different ways. In some cases, an augmented-reality or virtual-reality headset may initiate a DOA analysis to determine the location of a sound source. The DOA analysis may include analyzing the intensity, spectra, and/or arrival time of each sound at the artificial-reality device to determine the direction from which the sounds originated. The DOA analysis may include any suitable algorithm for analyzing the surrounding acoustic environment in which the artificial-r-eality device is located.

For example, the DOA analysis may be designed to receive input signals from a microphone and apply digital signal processing algorithms to the input signals to estimate the direction of arrival. These algorithms may include, for example, delay and sum algorithms where the input signal is sampled, and the resulting weighted and delayed versions of the sampled signal are averaged together to determine a direction of arrival. A least mean squared (LMS) algorithm may also be implemented to create an adaptive filter. This adaptive filter may then be used to identify differences in signal intensity, for example, or differences in time of arrival. These differences may then be used to estimate the direction of arrival. In another embodiment, the DOA may be determined by converting the input signals into the frequency domain and selecting specific bins within the time-frequency (TF) domain to process. Each selected TF bin may be processed to determine whether that bin includes a portion of the audio spectrum with a direct-path audio signal. Those bins having a portion of the direct-path signal may then be analyzed to identify the angle at which a microphone array received the direct-path audio signal. The determined angle may then be used to identify the direction of arrival for the received input signal. Other algorithms not listed above may also be used alone or in combination with the above algorithms to determine DOA.

In some embodiments, different users may perceive the source of a sound as coming from slightly different locations. This may be the result of each user having a unique head-related transfer function (HRTF), which may be dictated by a user's anatomy including ear canal length and the positioning of the ear drum. The artificial-reality device may provide an alignment and orientation guide, which the user may follow to customize the sound signal presented to the user based on their unique HRTF. In some embodiments, an artificial-reality device may implement one or more microphones to listen to sounds within the user's environment. The augmented-reality or virtual-reality headset may use a variety of different array transfer functions (e.g., any of the DOA algorithms identified above) to estimate the direction of arrival for the sounds. Once the direction of arrival has been determined, the artificial-reality device may play back sounds to the user according to the user's unique HRTF. Accordingly, the DOA estimation generated using the array transfer function (ATF) may be used to determine the direction from which the sounds are to be played from. The playback sounds may be further refined based on how that specific user hears sounds according to the HRTF.

In addition to or as an alternative to performing a DOA estimation, an artificial-reality device may perform localization based on information received from other types of sensors. These sensors may include cameras, IR sensors, heat sensors, motion sensors, GPS receivers, or in some cases, sensors that detect a user's eye movements. For example, as noted above, an artificial-reality device may include an eye tracker or gaze detector that determines where the user is looking. Often, the user's eyes will look at the source of the sound, if only briefly. Such clues provided by the user's eyes may further aid in determining the location of a sound source. Other sensors such as cameras, heat sensors, and IR sensors may also indicate the location of a user, the location of an electronic device, or the location of another sound source. Any or all of the above methods may be used individually or in combination to determine the location of a sound source and may further be used to update the location of a sound source over time.

Some embodiments may implement the determined DOA to generate a more customized output audio signal for the user. For instance, an “acoustic transfer function” may characterize or define how a sound is received from a given location. More specifically, an acoustic transfer function may define the relationship between parameters of a sound at its source location and the parameters by which the sound signal is detected (e.g., detected by a microphone array or detected by a user's ear). An artificial-reality device may include one or more acoustic sensors that detect sounds within range of the device. A controller of the artificial-reality device may estimate a DOA for the detected sounds (using, e.g., any of the methods identified above) and, based on the parameters of the detected sounds, may generate an acoustic transfer function that is specific to the location of the device. This customized acoustic transfer function may thus be used to generate a spatialized output audio signal where the sound is perceived as coming from a specific location.

Indeed, once the location of the sound source or sources is known, the artificial-reality device may re-render (i.e., spatialize) the sound signals to sound as if coming from the direction of that sound source. The artificial-reality device may apply filters or other digital signal processing that alter the intensity, spectra, or arrival time of the sound signal. The digital signal processing may be applied in such a way that the sound signal is perceived as originating from the determined location. The artificial-reality device may amplify or subdue certain frequencies or change the time that the signal arrives at each ear. In some cases, the artificial-reality device may create an acoustic transfer function that is specific to the location of the device and the detected direction of arrival of the sound signal. In some embodiments, the artificial-reality device may re-render the source signal in a stereo device or multi-speaker device (e.g., a surround sound device). In such cases, separate and distinct audio signals may be sent to each speaker. Each of these audio signals may be altered according to the user's HRTF and according to measurements of the user's location and the location of the sound source to sound as if they are coming from the determined location of the sound source. Accordingly, in this manner, the artificial-reality device (or speakers associated with the device) may re-render an audio signal to sound as if originating from a specific location.

As noted, artificial-reality systems 700 and 800 may be used with a variety of other types of devices to provide a more compelling artificial-reality experience. These devices may be haptic interfaces with transducers that provide haptic feedback and/or that collect haptic information about a user's interaction with an environment. The artificial-reality systems disclosed herein may include various types of haptic interfaces that detect or convey various types of haptic information, including tactile feedback (e.g., feedback that a user detects via nerves in the skin, which may also be referred to as cutaneous feedback) and/or kinesthetic feedback (e.g., feedback that a user detects via receptors located in muscles, joints, and/or tendons).

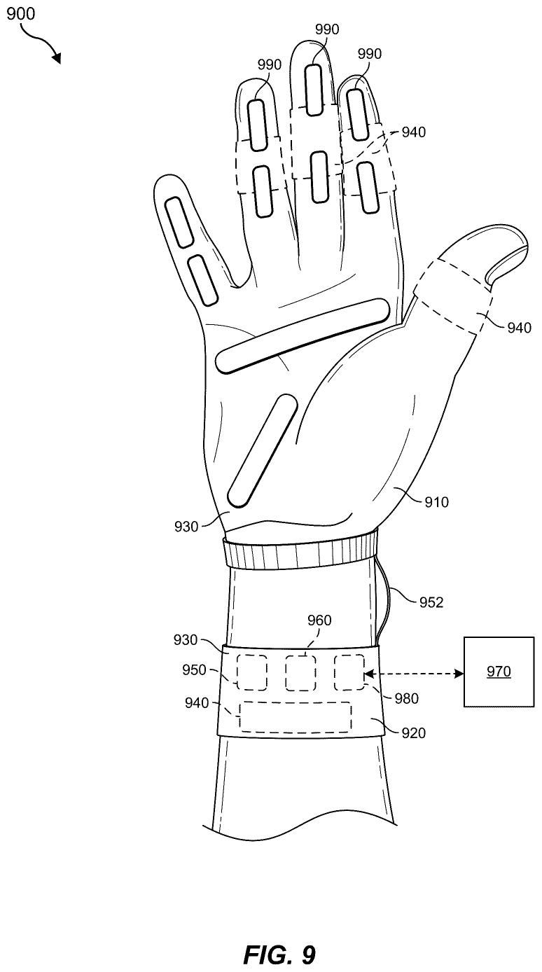

Haptic feedback may be provided by interfaces positioned within a user's environment (e.g., chairs, tables, floors, etc.) and/or interfaces on articles that may be worn or carried by a user (e.g., gloves, wristbands, etc.). As an example, FIG. 9 illustrates a vibrotactile system 900 in the form of a wearable glove (haptic device 910) and wristband (haptic device 920). Haptic device 910 and haptic device 920 are shown as examples of wearable devices that include a flexible, wearable textile material 930 that is shaped and configured for positioning against a user's hand and wrist, respectively. This disclosure also includes vibrotactile systems that may be shaped and configured for positioning against other human body parts, such as a finger, an arm, a head, a torso, a foot, or a leg. By way of example and not limitation, vibrotactile systems according to various embodiments of the present disclosure may also be in the form of a glove, a headband, an armband, a sleeve, a head covering, a sock, a shirt, or pants, among other possibilities. In some examples, the term “textile” may include any flexible, wearable material, including woven fabric, non-woven fabric, leather, cloth, a flexible polymer material, composite materials, etc.

One or more vibrotactile devices 940 may be positioned at least partially within one or more corresponding pockets formed in textile material 930 of vibrotactile system 900. Vibrotactile devices 940 may be positioned in locations to provide a vibrating sensation (e.g., haptic feedback) to a user of vibrotactile system 900. For example, vibrotactile devices 940 may be positioned against the user's finger(s), thumb, or wrist, as shown in FIG. 9. Vibrotactile devices 940 may, in some examples, be sufficiently flexible to conform to or bend with the user's corresponding body part(s).

A power source 950 (e.g., a battery) for applying a voltage to the vibrotactile devices 940 for activation thereof may be electrically coupled to vibrotactile devices 940, such as via conductive wiring 952. In some examples, each of vibrotactile devices 940 may be independently electrically coupled to power source 950 for individual activation. In some embodiments, a processor 960 may be operatively coupled to power source 950 and configured (e.g., programmed) to control activation of vibrotactile devices 940.

Vibrotactile system 900 may be implemented in a variety of ways. In some examples, vibrotactile system 900 may be a standalone system with integral subsystems and components for operation independent of other devices and systems. As another example, vibrotactile system 900 may be configured for interaction with another device or system 970. For example, vibrotactile system 900 may, in some examples, include a communications interface 980 for receiving and/or sending signals to the other device or system 970. The other device or system 970 may be a mobile device, a gaming console, an artificial-reality (e.g., virtual-reality, augmented-reality, mixed-reality) device, a personal computer, a tablet computer, a network device (e.g., a modem, a router, etc.), a handheld controller, etc. Communications interface 980 may enable communications between vibrotactile system 900 and the other device or system 970 via a wireless (e.g., Wi-Fi, BLUETOOTH, cellular, radio, etc.) link or a wired link. If present, communications interface 980 may be in communication with processor 960, such as to provide a signal to processor 960 to activate or deactivate one or more of the vibrotactile devices 940.

Vibrotactile system 900 may optionally include other subsystems and components, such as touch-sensitive pads 990, pressure sensors, motion sensors, position sensors, lighting elements, and/or user interface elements (e.g., an on/off button, a vibration control element, etc.). During use, vibrotactile devices 940 may be configured to be activated for a variety of different reasons, such as in response to the user's interaction with user interface elements, a signal from the motion or position sensors, a signal from the touch-sensitive pads 990, a signal from the pressure sensors, a signal from the other device or system 970, etc.

Although power source 950, processor 960, and communications interface 980 are illustrated in FIG. 9 as being positioned in haptic device 920, the present disclosure is not so limited. For example, one or more of power source 950, processor 960, or communications interface 980 may be positioned within haptic device 910 or within another wearable textile.

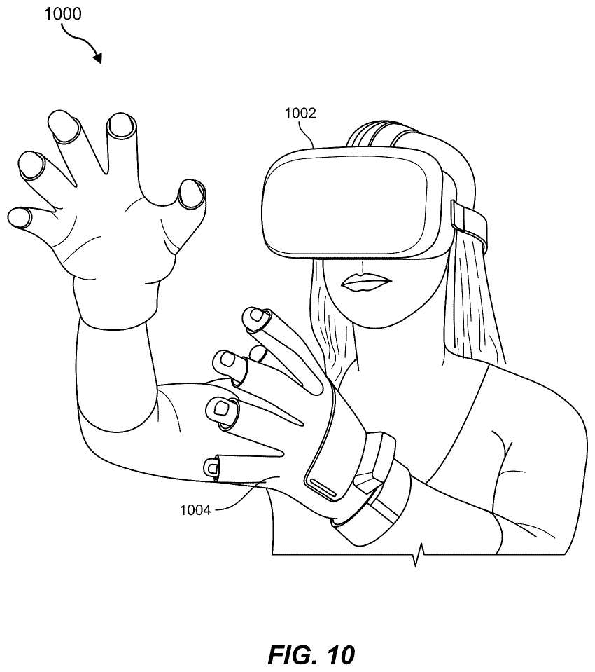

Haptic wearables, such as those shown in and described in connection with FIG. 9, may be implemented in a variety of types of artificial-reality systems and environments. FIG. 10 shows an example artificial-reality environment 1000 including one head-mounted virtual-reality display and two haptic devices (i.e., gloves), and in other embodiments any number and/or combination of these components and other components may be included in an artificial-reality system. For example, in some embodiments there may be multiple head-mounted displays each having an associated haptic device, with each head-mounted display and each haptic device communicating with the same console, portable computing device, or other computing system.

Head-mounted display 1002 generally represents any type or form of virtual-reality system, such as virtual-reality system 800 in FIG. 8. Haptic device 1004 generally represents any type or form of wearable device, worn by a user of an artificial-reality system, that provides haptic feedback to the user to give the user the perception that he or she is physically engaging with a virtual object. In some embodiments, haptic device 1004 may provide haptic feedback by applying vibration, motion, and/or force to the user. For example, haptic device 1004 may limit or augment a user's movement. To give a specific example, haptic device 1004 may limit a user's hand from moving forward so that the user has the perception that his or her hand has come in physical contact with a virtual wall. In this specific example, one or more actuators within the haptic device may achieve the physical-movement restriction by pumping fluid into an inflatable bladder of the haptic device. In some examples, a user may also use haptic device 1004 to send action requests to a console. Examples of action requests include, without limitation, requests to start an application and/or end the application and/or requests to perform a particular action within the application.

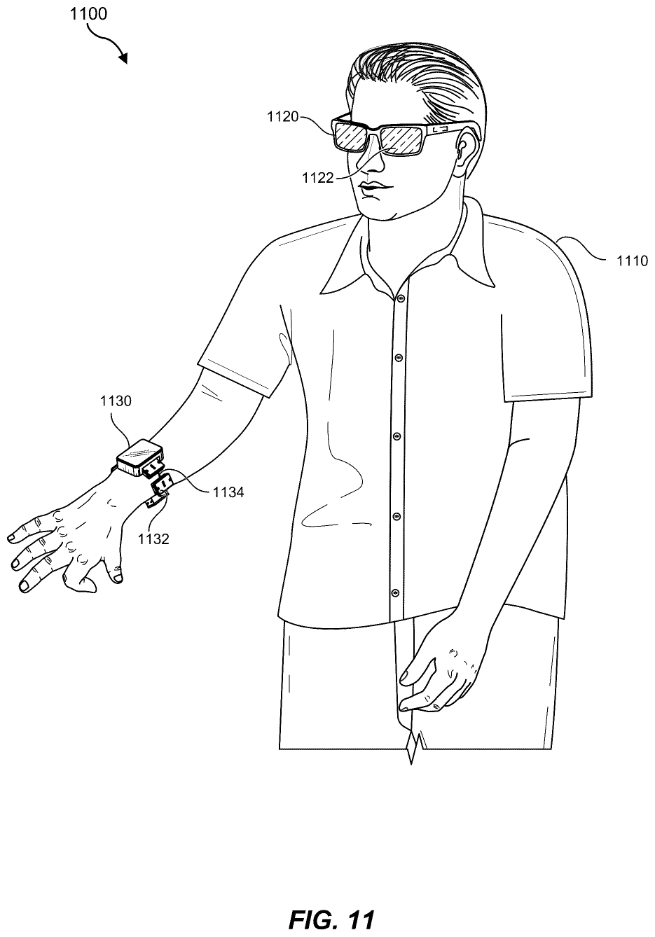

While haptic interfaces may be used with virtual-reality systems, as shown in FIG. 10, haptic interfaces may also be used with augmented-reality systems, as shown in FIG. 11. FIG. 11 is a perspective view of a user 1110 interacting with an augmented-reality system 1100. In this example, user 1110 may wear a pair of augmented-reality glasses 1120 that may have one or more displays 1122 and that are paired with a haptic device 1130. In this example, haptic device 1130 may be a wristband that includes a plurality of band elements 1132 and a tensioning mechanism 1134 that connects band elements 1132 to one another.

One or more of band elements 1132 may include any type or form of actuator suitable for providing haptic feedback. For example, one or more of band elements 1132 may be configured to provide one or more of various types of cutaneous feedback, including vibration, force, traction, texture, and/or temperature. To provide such feedback, band elements 1132 may include one or more of various types of actuators. In one example, each of band elements 1132 may include a vibrotactor (e.g., a vibrotactile actuator) configured to vibrate in unison or independently to provide one or more of various types of haptic sensations to a user. Alternatively, only a single band element or a subset of band elements may include vibrotactors.

Haptic devices 910, 920, 1004, and 1130 may include any suitable number and/or type of haptic transducer, sensor, and/or feedback mechanism. For example, haptic devices 910, 920, 1004, and 1130 may include one or more mechanical transducers, piezoelectric transducers, and/or fluidic transducers. Haptic devices 910, 920, 1004, and 1130 may also include various combinations of different types and forms of transducers that work together or independently to enhance a user's artificial-reality experience. In one example, each of band elements 1132 of haptic device 1130 may include a vibrotactor (e.g., a vibrotactile actuator) configured to vibrate in unison or independently to provide one or more of various types of haptic sensations to a user.

In some embodiments, the systems described herein may also include an eye-tracking subsystem designed to identify and track various characteristics of a user's eye(s), such as the user's gaze direction. The phrase “eye tracking” may, in some examples, refer to a process by which the position, orientation, and/or motion of an eye is measured, detected, sensed, determined, and/or monitored. The disclosed systems may measure the position, orientation, and/or motion of an eye in a variety of different ways, including through the use of various optical-based eye-tracking techniques, ultrasound-based eye-tracking techniques, etc. An eye-tracking subsystem may be configured in a number of different ways and may include a variety of different eye-tracking hardware components or other computer-vision components. For example, an eye-tracking subsystem may include a variety of different optical sensors, such as two-dimensional (2D) or 3D cameras, time-of-flight depth sensors, single-beam or sweeping laser rangefinders, 3D LiDAR sensors, and/or any other suitable type or form of optical sensor. In this example, a processing subsystem may process data from one or more of these sensors to measure, detect, determine, and/or otherwise monitor the position, orientation, and/or motion of the user's eye(s).

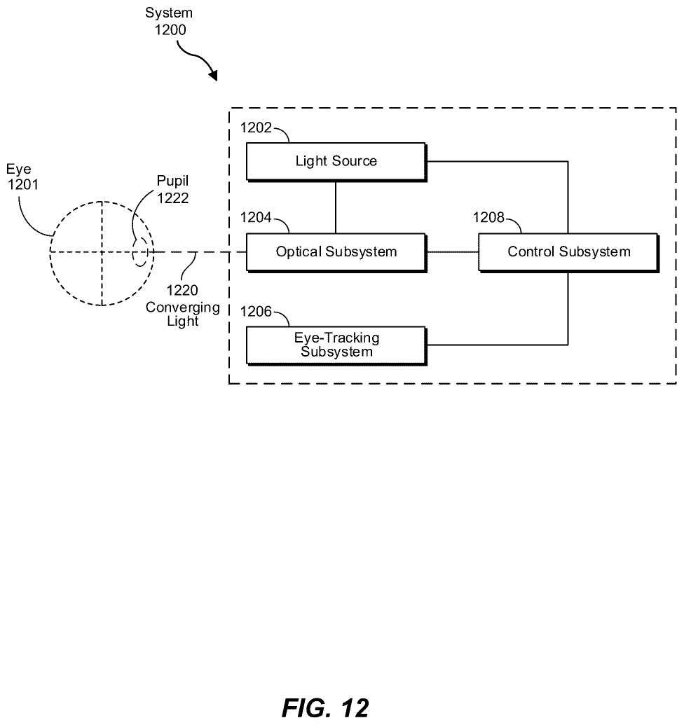

FIG. 12 is an illustration of an exemplary system 1200 that incorporates an eye-tracking subsystem capable of tracking a user's eye(s). As depicted in FIG. 12, system 1200 may include a light source 1202, an optical subsystem 1204, an eye-tracking subsystem 1206, and/or a control subsystem 1208. In some examples, light source 1202 may generate light for an image (e.g., to be presented to an eye 1201 of the viewer). Light source 1202 may represent any of a variety of suitable devices. For example, light source 1202 can include a two-dimensional projector (e.g., a LCOS display), a scanning source (e.g., a scanning laser), or other device (e.g., an LCD, an LED display, an OLED display, an active-matrix OLED display (AMOLED), a transparent OLED display (TOLED), a waveguide, or some other display capable of generating light for presenting an image to the viewer). In some examples, the image may represent a virtual image, which may refer to an optical image formed from the apparent divergence of light rays from a point in space, as opposed to an image formed from the light ray's actual divergence.

In some embodiments, optical subsystem 1204 may receive the light generated by light source 1202 and generate, based on the received light, converging light 1220 that includes the image. In some examples, optical subsystem 1204 may include any number of lenses (e.g., Fresnel lenses, convex lenses, concave lenses), apertures, filters, mirrors, prisms, and/or other optical components, possibly in combination with actuators and/or other devices. In particular, the actuators and/or other devices may translate and/or rotate one or more of the optical components to alter one or more aspects of converging light 1220. Further, various mechanical couplings may serve to maintain the relative spacing and/or the orientation of the optical components in any suitable combination.

In one embodiment, eye-tracking subsystem 1206 may generate tracking information indicating a gaze angle of an eye 1201 of the viewer. In this embodiment, control subsystem 1208 may control aspects of optical subsystem 1204 (e.g., the angle of incidence of converging light 1220) based at least in part on this tracking information. Additionally, in some examples, control subsystem 1208 may store and utilize historical tracking information (e.g., a history of the tracking information over a given duration, such as the previous second or fraction thereof) to anticipate the gaze angle of eye 1201 (e.g., an angle between the visual axis and the anatomical axis of eye 1201). In some embodiments, eye-tracking subsystem 1206 may detect radiation emanating from some portion of eye 1201 (e.g., the cornea, the iris, the pupil, or the like) to determine the current gaze angle of eye 1201. In other examples, eye-tracking subsystem 1206 may employ a wavefront sensor to track the current location of the pupil.

Any number of techniques can be used to track eye 1201. Some techniques may involve illuminating eye 1201 with infrared light and measuring reflections with at least one optical sensor that is tuned to be sensitive to the infrared light. Information about how the infrared light is reflected from eye 1201 may be analyzed to determine the position(s), orientation(s), and/or motion(s) of one or more eye feature(s), such as the cornea, pupil, iris, and/or retinal blood vessels.

In some examples, the radiation captured by a sensor of eye-tracking subsystem 1206 may be digitized (i.e., converted to an electronic signal). Further, the sensor may transmit a digital representation of this electronic signal to one or more processors (for example, processors associated with a device including eye-tracking subsystem 1206). Eye-tracking subsystem 1206 may include any of a variety of sensors in a variety of different configurations. For example, eye-tracking subsystem 1206 may include an infrared detector that reacts to infrared radiation. The infrared detector may be a thermal detector, a photonic detector, and/or any other suitable type of detector. Thermal detectors may include detectors that react to thermal effects of the incident infrared radiation.

In some examples, one or more processors may process the digital representation generated by the sensor(s) of eye-tracking subsystem 1206 to track the movement of eye 1201. In another example, these processors may track the movements of eye 1201 by executing algorithms represented by computer-executable instructions stored on non-transitory memory. In some examples, on-chip logic (e.g., an application-specific integrated circuit or ASIC) may be used to perform at least portions of such algorithms. As noted, eye-tracking subsystem 1206 may be programmed to use an output of the sensor(s) to track movement of eye 1201. In some embodiments, eye-tracking subsystem 1206 may analyze the digital representation generated by the sensors to extract eye rotation information from changes in reflections. In one embodiment, eye-tracking subsystem 1206 may use corneal reflections or glints (also known as Purkinje images) and/or the center of the eye's pupil 1222 as features to track over time.

In some embodiments, eye-tracking subsystem 1206 may use the center of the eye's pupil 1222 and infrared or near-infrared, non-collimated light to create corneal reflections. In these embodiments, eye-tracking subsystem 1206 may use the vector between the center of the eye's pupil 1222 and the corneal reflections to compute the gaze direction of eye 1201. In some embodiments, the disclosed systems may perform a calibration procedure for an individual (using, e.g., supervised or unsupervised techniques) before tracking the user's eyes. For example, the calibration procedure may include directing users to look at one or more points displayed on a display while the eye-tracking system records the values that correspond to each gaze position associated with each point.

In some embodiments, eye-tracking subsystem 1206 may use two types of infrared and/or near-infrared (also known as active light) eye-tracking techniques: bright-pupil and dark-pupil eye tracking, which may be differentiated based on the location of an illumination source with respect to the optical elements used. If the illumination is coaxial with the optical path, then eye 1201 may act as a retroreflector as the light reflects off the retina, thereby creating a bright pupil effect similar to a red-eye effect in photography. If the illumination source is offset from the optical path, then the eye's pupil 1222 may appear dark because the retroreflection from the retina is directed away from the sensor. In some embodiments, bright-pupil tracking may create greater iris/pupil contrast, allowing more robust eye tracking with iris pigmentation, and may feature reduced interference (e.g., interference caused by eyelashes and other obscuring features). Bright-pupil tracking may also allow tracking in lighting conditions ranging from total darkness to a very bright environment.

In some embodiments, control subsystem 1208 may control light source 1202 and/or optical subsystem 1204 to reduce optical aberrations (e.g., chromatic aberrations and/or monochromatic aberrations) of the image that may be caused by or influenced by eye 1201. In some examples, as mentioned above, control subsystem 1208 may use the tracking information from eye-tracking subsystem 1206 to perform such control. For example, in controlling light source 1202, control subsystem 1208 may alter the light generated by light source 1202 (e.g., by way of image rendering) to modify (e.g., pre-distort) the image so that the aberration of the image caused by eye 1201 is reduced.

The disclosed systems may track both the position and relative size of the pupil (since, e.g., the pupil dilates and/or contracts). In some examples, the eye-tracking devices and components (e.g., sensors and/or sources) used for detecting and/or tracking the pupil may be different (or calibrated differently) for different types of eyes. For example, the frequency range of the sensors may be different (or separately calibrated) for eyes of different colors and/or different pupil types, sizes, and/or the like. As such, the various eye-tracking components (e.g., infrared sources and/or sensors) described herein may need to be calibrated for each individual user and/or eye.

The disclosed systems may track both eyes with and without ophthalmic correction, such as that provided by contact lenses worn by the user. In some embodiments, ophthalmic correction elements (e.g., adjustable lenses) may be directly incorporated into the artificial reality systems described herein. In some examples, the color of the user's eye may necessitate modification of a corresponding eye-tracking algorithm. For example, eye-tracking algorithms may need to be modified based at least in part on the differing color contrast between a brown eye and, for example, a blue eye.

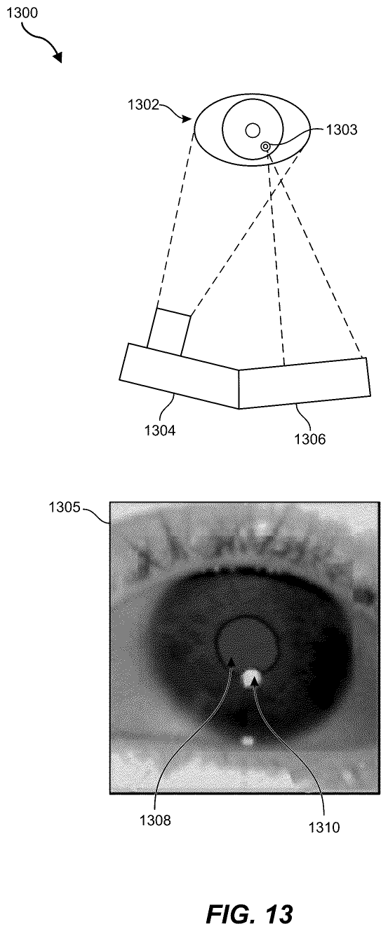

FIG. 13 is a more detailed illustration of various aspects of the eye-tracking subsystem illustrated in FIG. 12. As shown in this figure, an eye-tracking subsystem 1300 may include at least one source 1304 and at least one sensor 1306. Source 1304 generally represents any type or form of element capable of emitting radiation. In one example, source 1304 may generate visible, infrared, and/or near-infrared radiation. In some examples, source 1304 may radiate non-collimated infrared and/or near-infrared portions of the electromagnetic spectrum towards an eye 1302 of a user. Source 1304 may utilize a variety of sampling rates and speeds. For example, the disclosed systems may use sources with higher sampling rates in order to capture fixational eye movements of a user's eye 1302 and/or to correctly measure saccade dynamics of the user's eye 1302. As noted above, any type or form of eye-tracking technique may be used to track the user's eye 1302, including optical-based eye-tracking techniques, ultrasound-based eye-tracking techniques, etc.

Sensor 1306 generally represents any type or form of element capable of detecting radiation, such as radiation reflected off the user's eye 1302. Examples of sensor 1306 include, without limitation, a charge coupled device (CCD), a photodiode array, a complementary metal-oxide-semiconductor (CMOS) based sensor device, and/or the like. In one example, sensor 1306 may represent a sensor having predetermined parameters, including, but not limited to, a dynamic resolution range, linearity, and/or other characteristic selected and/or designed specifically for eye tracking.

As detailed above, eye-tracking subsystem 1300 may generate one or more glints. As detailed above, a glint 1303 may represent reflections of radiation (e.g., infrared radiation from an infrared source, such as source 1304) from the structure of the user's eye. In various embodiments, glint 1303 and/or the user's pupil may be tracked using an eye-tracking algorithm executed by a processor (either within or external to an artificial reality device). For example, an artificial reality device may include a processor and/or a memory device in order to perform eye tracking locally and/or a transceiver to send and receive the data necessary to perform eye tracking on an external device (e.g., a mobile phone, cloud server, or other computing device).

FIG. 13 shows an example image 1305 captured by an eye-tracking subsystem, such as eye-tracking subsystem 1300. In this example, image 1305 may include both the user's pupil 1308 and a glint 1310 near the same. In some examples, pupil 1308 and/or glint 1310 may be identified using an artificial-intelligence-based algorithm, such as a computer-vision-based algorithm. In one embodiment, image 1305 may represent a single frame in a series of frames that may be analyzed continuously in order to track the eye 1302 of the user. Further, pupil 1308 and/or glint 1310 may be tracked over a period of time to determine a user's gaze.

In one example, eye-tracking subsystem 1300 may be configured to identify and measure the inter-pupillary distance (IPD) of a user. In some embodiments, eye-tracking subsystem 1300 may measure and/or calculate the IPD of the user while the user is wearing the artificial reality system. In these embodiments, eye-tracking subsystem 1300 may detect the positions of a user's eyes and may use this information to calculate the user's IPD.

As noted, the eye-tracking systems or subsystems disclosed herein may track a user's eye position and/or eye movement in a variety of ways. In one example, one or more light sources and/or optical sensors may capture an image of the user's eyes. The eye-tracking subsystem may then use the captured information to determine the user's inter-pupillary distance, interocular distance, and/or a 3D position of each eye (e.g., for distortion adjustment purposes), including a magnitude of torsion and rotation (i.e., roll, pitch, and yaw) and/or gaze directions for each eye. In one example, infrared light may be emitted by the eye-tracking subsystem and reflected from each eye. The reflected light may be received or detected by an optical sensor and analyzed to extract eye rotation data from changes in the infrared light reflected by each eye.

The eye-tracking subsystem may use any of a variety of different methods to track the eyes of a user. For example, a light source (e.g., infrared light-emitting diodes) may emit a dot pattern onto each eye of the user. The eye-tracking subsystem may then detect (e.g., via an optical sensor coupled to the artificial reality system) and analyze a reflection of the dot pattern from each eye of the user to identify a location of each pupil of the user. Accordingly, the eye-tracking subsystem may track up to six degrees of freedom of each eye (i.e., 3D position, roll, pitch, and yaw) and at least a subset of the tracked quantities may be combined from two eyes of a user to estimate a gaze point (i.e., a 3D location or position in a virtual scene where the user is looking) and/or an IPD.

In some cases, the distance between a user's pupil and a display may change as the user's eye moves to look in different directions. The varying distance between a pupil and a display as viewing direction changes may be referred to as “pupil swim” and may contribute to distortion perceived by the user as a result of light focusing in different locations as the distance between the pupil and the display changes. Accordingly, measuring distortion at different eye positions and pupil distances relative to displays and generating distortion corrections for different positions and distances may allow mitigation of distortion caused by pupil swim by tracking the 3D position of a user's eyes and applying a distortion correction corresponding to the 3D position of each of the user's eyes at a given point in time. Thus, knowing the 3D position of each of a user's eyes may allow for the mitigation of distortion caused by changes in the distance between the pupil of the eye and the display by applying a distortion correction for each 3D eye position. Furthermore, as noted above, knowing the position of each of the user's eyes may also enable the eye-tracking subsystem to make automated adjustments for a user's IPD.

In some embodiments, a display subsystem may include a variety of additional subsystems that may work in conjunction with the eye-tracking subsystems described herein. For example, a display subsystem may include a varifocal subsystem, a scene-rendering module, and/or a vergence-processing module. The varifocal subsystem may cause left and right display elements to vary the focal distance of the display device. In one embodiment, the varifocal subsystem may physically change the distance between a display and the optics through which it is viewed by moving the display, the optics, or both. Additionally, moving or translating two lenses relative to each other may also be used to change the focal distance of the display. Thus, the varifocal subsystem may include actuators or motors that move displays and/or optics to change the distance between them. This varifocal subsystem may be separate from or integrated into the display subsystem. The varifocal subsystem may also be integrated into or separate from its actuation subsystem and/or the eye-tracking subsystems described herein.

In one example, the display subsystem may include a vergence-processing module configured to determine a vergence depth of a user's gaze based on a gaze point and/or an estimated intersection of the gaze lines determined by the eye-tracking subsystem. Vergence may refer to the simultaneous movement or rotation of both eyes in opposite directions to maintain single binocular vision, which may be naturally and automatically performed by the human eye. Thus, a location where a user's eyes are verged is where the user is looking and is also typically the location where the user's eyes are focused. For example, the vergence-processing module may triangulate gaze lines to estimate a distance or depth from the user associated with intersection of the gaze lines. The depth associated with intersection of the gaze lines may then be used as an approximation for the accommodation distance, which may identify a distance from the user where the user's eyes are directed. Thus, the vergence distance may allow for the determination of a location where the user's eyes should be focused and a depth from the user's eyes at which the eyes are focused, thereby providing information (such as an object or plane of focus) for rendering adjustments to the virtual scene.

The vergence-processing module may coordinate with the eye-tracking subsystems described herein to make adjustments to the display subsystem to account for a user's vergence depth. When the user is focused on something at a distance, the user's pupils may be slightly farther apart than when the user is focused on something close. The eye-tracking subsystem may obtain information about the user's vergence or focus depth and may adjust the display subsystem to be closer together when the user's eyes focus or verge on something close and to be farther apart when the user's eyes focus or verge on something at a distance.

The eye-tracking information generated by the above-described eye-tracking subsystems may also be used, for example, to modify various aspect of how different computer-generated images are presented. For example, a display subsystem may be configured to modify, based on information generated by an eye-tracking subsystem, at least one aspect of how the computer-generated images are presented. For instance, the computer-generated images may be modified based on the user's eye movement, such that if a user is looking up, the computer-generated images may be moved upward on the screen. Similarly, if the user is looking to the side or down, the computer-generated images may be moved to the side or downward on the screen. If the user's eyes are closed, the computer-generated images may be paused or removed from the display and resumed once the user's eyes are back open.

The above-described eye-tracking subsystems can be incorporated into one or more of the various artificial reality systems described herein in a variety of ways. For example, one or more of the various components of system 1200 and/or eye-tracking subsystem 1300 may be incorporated into augmented-reality system 700 in FIG. 7 and/or virtual-reality system 800 in FIG. 8 to enable these systems to perform various eye-tracking tasks (including one or more of the eye-tracking operations described herein).

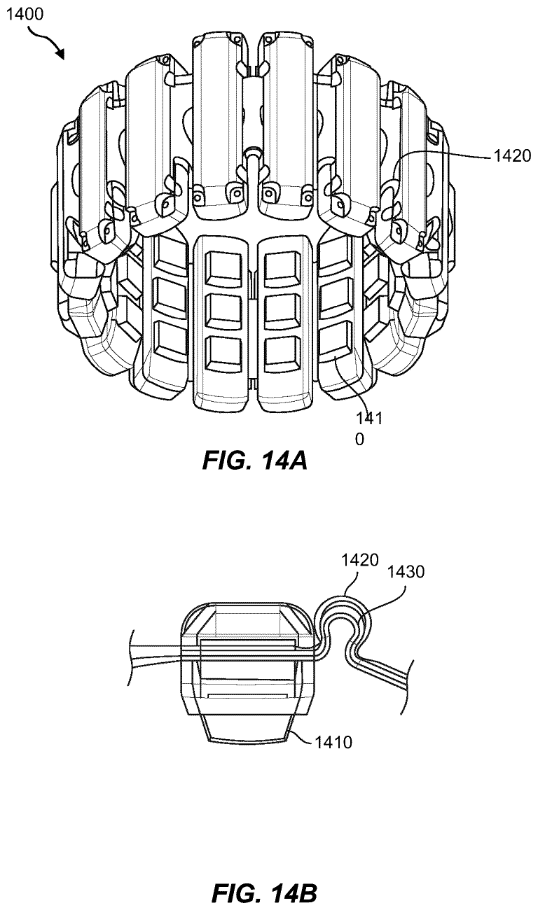

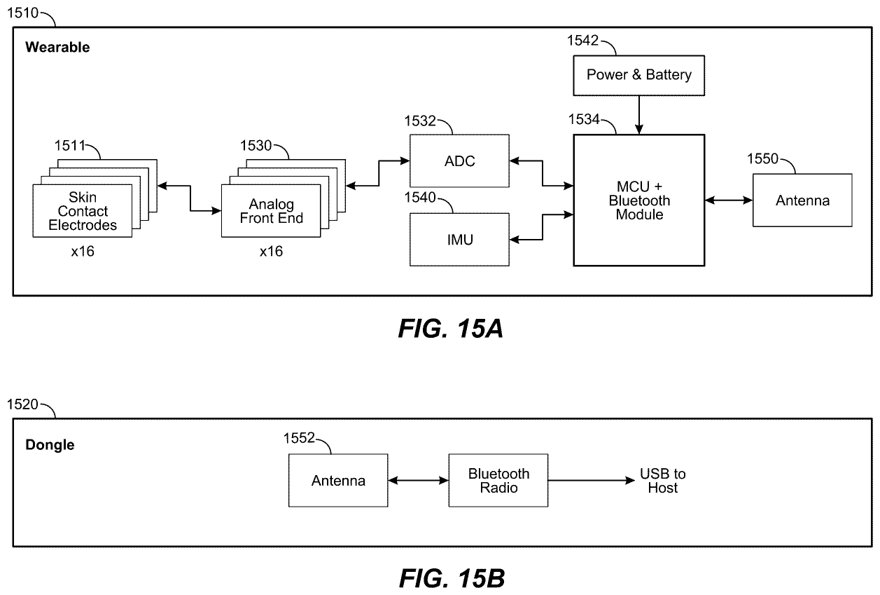

FIG. 14A illustrates an exemplary human-machine interface (also referred to herein as an EMG control interface) configured to be worn around a user's lower arm or wrist as a wearable system 1400. In this example, wearable system 1400 may include sixteen neuromuscular sensors 1410 (e.g., EMG sensors) arranged circumferentially around an elastic band 1420 with an interior surface 1430 configured to contact a user's skin. However, any suitable number of neuromuscular sensors may be used. The number and arrangement of neuromuscular sensors may depend on the particular application for which the wearable device is used. For example, a wearable armband or wristband can be used to generate control information for controlling an augmented reality system, a robot, controlling a vehicle, scrolling through text, controlling a virtual avatar, or any other suitable control task. As shown, the sensors may be coupled together using flexible electronics incorporated into the wireless device. FIG. 14B illustrates a cross-sectional view through one of the sensors of the wearable device shown in FIG. 14A. In some embodiments, the output of one or more of the sensing components can be optionally processed using hardware signal processing circuitry (e.g., to perform amplification, filtering, and/or rectification). In other embodiments, at least some signal processing of the output of the sensing components can be performed in software. Thus, signal processing of signals sampled by the sensors can be performed in hardware, software, or by any suitable combination of hardware and software, as aspects of the technology described herein are not limited in this respect. A non-limiting example of a signal processing chain used to process recorded data from sensors 1410 is discussed in more detail below with reference to FIGS. 15A and 15B.

FIGS. 15A and 15B illustrate an exemplary schematic diagram with internal components of a wearable system with EMG sensors. As shown, the wearable system may include a wearable portion 1510 (FIG. 15A) and a dongle portion 1520 (FIG. 15B) in communication with the wearable portion 1510 (e.g., via BLUETOOTH or another suitable wireless communication technology). As shown in FIG. 15A, the wearable portion 1510 may include skin contact electrodes 1511, examples of which are described in connection with FIGS. 14A and 14B. The output of the skin contact electrodes 1511 may be provided to analog front end 1530, which may be configured to perform analog processing (e.g., amplification, noise reduction, filtering, etc.) on the recorded signals. The processed analog signals may then be provided to analog-to-digital converter 1532, which may convert the analog signals to digital signals that can be processed by one or more computer processors. An example of a computer processor that may be used in accordance with some embodiments is microcontroller (MCU) 1534, illustrated in FIG. 15A. As shown, MCU 1534 may also include inputs from other sensors (e.g., IMU sensor 1540), and power and battery module 1542. The output of the processing performed by MCU 1534 may be provided to antenna 1550 for transmission to dongle portion 1520 shown in FIG. 15B.

Dongle portion 1520 may include antenna 1552, which may be configured to communicate with antenna 1550 included as part of wearable portion 1510. Communication between antennas 1550 and 1552 may occur using any suitable wireless technology and protocol, non-limiting examples of which include radiofrequency signaling and BLUETOOTH. As shown, the signals received by antenna 1552 of dongle portion 1520 may be provided to a host computer for further processing, display, and/or for effecting control of a particular physical or virtual object or objects.

Although the examples provided with reference to FIGS. 14A-14B and FIGS. 15A-15B are discussed in the context of interfaces with EMG sensors, the techniques described herein for reducing electromagnetic interference can also be implemented in wearable interfaces with other types of sensors including, but not limited to, mechanomyography (MMG) sensors, sonomyography (SMG) sensors, and electrical impedance tomography (EIT) sensors. The techniques described herein for reducing electromagnetic interference can also be implemented in wearable interfaces that communicate with computer hosts through wires and cables (e.g., USB cables, optical fiber cables, etc.).

As detailed above, the computing devices and systems described and/or illustrated herein broadly represent any type or form of computing device or system capable of executing computer-readable instructions, such as those contained within the modules described herein. In their most basic configuration, these computing device(s) may each include at least one memory device and at least one physical processor.

In some examples, the term “memory device” generally refers to any type or form of volatile or non-volatile storage device or medium capable of storing data and/or computer-readable instructions. In one example, a memory device may store, load, and/or maintain one or more of the modules described herein. Examples of memory devices include, without limitation, Random Access Memory (RAM), Read Only Memory (ROM), flash memory, Hard Disk Drives (HDDs), Solid-State Drives (SSDs), optical disk drives, caches, variations or combinations of one or more of the same, or any other suitable storage memory.

In some examples, the term “physical processor” generally refers to any type or form of hardware-implemented processing unit capable of interpreting and/or executing computer-readable instructions. In one example, a physical processor may access and/or modify one or more modules stored in the above-described memory device. Examples of physical processors include, without limitation, microprocessors, microcontrollers, Central Processing Units (CPUs), Field-Programmable Gate Arrays (FPGAs) that implement softcore processors, Application-Specific Integrated Circuits (ASICs), portions of one or more of the same, variations or combinations of one or more of the same, or any other suitable physical processor.

Although illustrated as separate elements, the modules described and/or illustrated herein may represent portions of a single module or application. In addition, in certain embodiments one or more of these modules may represent one or more software applications or programs that, when executed by a computing device, may cause the computing device to perform one or more tasks. For example, one or more of the modules described and/or illustrated herein may represent modules stored and configured to run on one or more of the computing devices or systems described and/or illustrated herein. One or more of these modules may also represent all or portions of one or more special-purpose computers configured to perform one or more tasks.

In addition, one or more of the modules described herein may transform data, physical devices, and/or representations of physical devices from one form to another. For example, one or more of the modules recited herein may transform a processor, volatile memory, non-volatile memory, and/or any other portion of a physical computing device from one form to another by executing on the computing device, storing data on the computing device, and/or otherwise interacting with the computing device.

In some embodiments, the term “computer-readable medium” generally refers to any form of device, carrier, or medium capable of storing or carrying computer-readable instructions. Examples of computer-readable media include, without limitation, transmission-type media, such as carrier waves, and non-transitory-type media, such as magnetic-storage media (e.g., hard disk drives, tape drives, and floppy disks), optical-storage media (e.g., Compact Disks (CDs), Digital Video Disks (DVDs), and BLU-RAY disks), electronic-storage media (e.g., solid-state drives and flash media), and other distribution systems.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. An artificial-reality system comprising:
an output device;
one or more real-world sensors; and
an integrated-circuit package comprising:
a general-purpose system-on-chip having a first die-to-die interface; and
a differentiated artificial-reality task-specific chiplet having a second die-to-die interface coupled to the first die-to-die interface of the general-purpose system-on-chip, wherein:
the differentiated artificial-reality task-specific chiplet is configured to generate an output by performing one or more differentiated artificial-reality processing tasks on one or more inputs derived from the one or more real-world sensors; and
the general-purpose system-on-chip is configured to present, via the output device, an artificial reality to a user based at least in part on the output of the differentiated artificial-reality task-specific chiplet.

2. The artificial-reality system of claim 1, wherein the one or more differentiated artificial-reality processing tasks comprise a deep-learning operation.

3. The artificial-reality system of claim 1, wherein the one or more differentiated artificial-reality processing tasks comprise a computer-vision operation.

4. The artificial-reality system of claim 1, wherein:
the general-purpose system-on-chip comprises an active frontside having first active circuitry;
the differentiated artificial-reality task-specific chiplet comprises an active frontside having second active circuitry;
the active frontside of the general-purpose system-on-chip faces a first direction; and
the active frontside of the differentiated artificial-reality task-specific chiplet faces a second direction opposite the first direction.

5. The artificial-reality system of claim 1 further comprising a redistribution layer, wherein the differentiated artificial-reality task-specific chiplet further comprises vias through which the general-purpose system-on-chip is electrically coupled to the redistribution layer.

6. The artificial-reality system of claim 1 further comprising:
a front housing configured to be worn against the face of the user, the front housing comprising:
the output device; and
the real-world sensor; and
a rear housing configured to be worn against the back of the user's head, the rear housing comprising:
the general-purpose system-on-chip; and
the differentiated artificial-reality task-specific chiplet.

7. The artificial-reality system of claim 1, wherein:
the integrated-circuit package further comprises an interposer; and
the general-purpose system-on-chip and the differentiated artificial-reality task-specific chiplet are coupled together via the interposer.

8. The artificial-reality system of claim 1, wherein:
the integrated-circuit package further comprises a redistribution layer; and
the general-purpose system-on-chip and the differentiated artificial-reality task-specific chiplet are coupled together via the redistribution layer.

9. The artificial-reality system of claim 1, wherein the first die-to-die interface of the general-purpose system-on-chip and the second die-to-die interface of the differentiated artificial-reality task-specific chiplet are universal chiplet interconnects.

10. A multi-chiplet assembly comprising:
a general-purpose system-on-chip comprising:
an active frontside having first active circuitry; and
a first die-to-die interface coupled to the first active circuitry; and
a differentiated artificial-reality task-specific chiplet comprising:
an active frontside having second active circuitry; and
a second die-to-die interface coupled to the second active circuitry and the first die-to-die interface of the general-purpose system-on-chip, wherein:
the differentiated artificial-reality task-specific chiplet is configured to generate an output by performing one or more differentiated artificial-reality processing tasks on one or more inputs derived from the one or more real-world sensors; and
the general-purpose system-on-chip is configured to present, via an output device, an artificial reality to a user based at least in part on the output of the differentiated artificial-reality task-specific chiplet.

11. The multi-chiplet assembly of claim 10, wherein the one or more differentiated artificial-reality processing tasks comprise a deep-learning operation.

12. The multi-chiplet assembly of claim 10, wherein the one or more differentiated artificial-reality processing tasks comprise a computer-vision operation.

13. The multi-chiplet assembly of claim 10, wherein:
the active frontside of the general-purpose system-on-chip faces a first direction; and
the active frontside of the differentiated artificial-reality task-specific chiplet faces a second direction opposite the first direction.

14. The multi-chiplet assembly of claim 10 further comprising a redistribution layer, wherein the differentiated artificial-reality task-specific chiplet further comprises vias through which the first active circuitry of the general-purpose system-on-chip is electrically coupled to the redistribution layer.

15. The multi-chiplet assembly of claim 10 further comprising an interposer, wherein the general-purpose system-on-chip and the differentiated artificial-reality task-specific chiplet are coupled together via the interposer.

16. The multi-chiplet assembly of claim 10 further comprising a redistribution layer, wherein the general-purpose system-on-chip and the differentiated artificial-reality task-specific chiplet are coupled together via the redistribution layer.

17. The multi-chiplet assembly of claim 10, wherein the first die-to-die interface of the general-purpose system-on-chip and the second die-to-die interface of the differentiated artificial-reality task-specific chiplet are universal chiplet interconnects.

18. A multi-chiplet assembly comprising:
a general-purpose system-on-chip comprising:
an active frontside having first active circuitry; and
a first die-to-die interface coupled to the first active circuitry; and
a differentiated artificial-reality task-specific chiplet comprising:
an active frontside having second active circuitry; and
a second die-to-die interface coupled to the second active circuitry and the first die-to-die interface of the general-purpose system-on-chip, wherein:
the active frontside of the general-purpose system-on-chip faces a first direction; and
the active frontside of the differentiated artificial-reality task-specific chiplet faces a second direction opposite the first direction.

19. The multi-chiplet assembly of claim 18 further comprising a redistribution layer, wherein the differentiated artificial-reality task-specific chiplet further comprises vias through which the first active circuitry of the general-purpose system-on-chip is electrically coupled to the redistribution layer.

20. The multi-chiplet assembly of claim 18, wherein the first die-to-die interface of the general-purpose system-on-chip and the second die-to-die interface of the differentiated artificial-reality task-specific chiplet are universal chiplet interconnects.
